(19) United States
(12) Patent Application Publication
(10) Pub. No.: US 2006/0159844 A1
(43) Pub. Date: Jul. 20, 2006

(54) Process and apparatus for producing magnetic recording medium

(75) Inventors: Kenichi Moriwaki, Kanagawa (JP); Kazuyuki Usuki, Kanagawa (JP); Junji Nakada, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/333,271

(22) Filed: Jan. 18, 2006

(30) Foreign Application Priority Data
Jan. 18, 2005 (JP) P.2005-010628
Dec. 22, 2005 (JP) P.2005-370552

(51) Int. Cl. B05D 5/12; C23C 16/00

(52) U.S. Cl. 427/127; 118/718

(57) ABSTRACT

A process for producing a magnetic recording medium comprising: unrolling a flexible polymer substrate from a feed roll; forming a magnetic layer on at least one side of the flexible polymer substrate by a vacuum film forming method in a film forming chamber; and taking up the flexible polymer substrate on a take-up roll, wherein at least one of the feed roll and the take-up roll is replaced while maintaining a vacuum state for forming the magnetic layer in the film forming chamber.

### FIELD OF THE INVENTION

The present invention relates to a process and an apparatus for producing a magnetic recording medium, the process comprising the steps of unrolling a flexible polymer substrate roll from a feed roll, forming a magnetic layer on at least one side of the flexible polymer substrate by a vacuum film forming method in a film forming chamber, and taking up the flexible polymer substrate on a take-up roll.

### BACKGROUND OF THE INVENTION

Recent popularization of the internet has diversified the use of personal computers, including processing large volumes of moving image or sound data. With this trend, the demand for magnetic recording media, such as hard disks, with increased memory capacity has ever been increasing.

In hard disk drives, when a magnetic disk is rotated, a magnetic head slightly flies from the magnetic disk surface to achieve noncontact magnetic recording. Thus, the magnetic head is prevented from coming into contact with the magnetic disk and damaging the disk. The floating height of the magnetic head has been decreasing with an increasing recording density. Today, a floating height as small as 10 to 20 nm has been realized by using a magnetic disk having a magnetic layer on a mirror-polished, super smooth glass substrate. In these few years, technological innovation including improvement on head structures and improvement on magnetic layers in addition to the reduction of head floating height has brought about drastic increases of surface recording density and recording capacity of hard disk drives.

The increase of processable digital data volume has created the need to store large-capacity data such as moving image data in a removable medium and to transfer the stored data. However, the hard disks have rigid substrates and the heads are only at a very short distance from the disks as described above, so that use of the hard disks as removable media like flexible disks or rewritable optical disks is limited on account of high possibility of troubles due to crashes or dust entrapment during rotation.

On the other hand, flexible disks and magnetic tapes have flexible polymer films as substrates and are capable of contact recording, and thus they are excellent in exchangeability and can be manufactured at lower cost. Currently available flexible disks and magnetic tapes comprise coating-type magnetic recording media prepared by applying magnetic substances together with polymer binders or abrasives to polymer films or deposition-type magnetic recording media prepared by vapor-depositing cobalt-based alloys in vacuo on polymer films. Compared with hard disks comprising magnetic layers formed by sputtering, such flexible disks and magnetic tapes are inferior in high density recording characteristics, achieving at the most, only one-tenth as much recording density as with the hard disks.

Ferromagnetic metal thin film flexible disks having magnetic layers formed by sputtering as in the manufacture of the hard disks have been proposed. The flexible disks use flexible polymer films as substrates, whereby the magnetic layers can be formed by sputtering while transferring a roll of the substrates. Thus, the magnetic recording media can be produced at low cost using the long substrates. Processes and apparatuses for producing such media are disclosed in JP-A-59-173266, P-A-5-274659, JP-A-7-235035, JP-A-10-3663, P-A-10-11734, JP-A-2002-367149, JP-A-2003-99918, WP-B-61-36862, JP-A-9-230538, JP-A-2001-93137, JP-A-2002-197633 and JP-A-2004-227621.

One problem encountered in the production of the magnetic recording media using the long substrates is that flakes are deposited on a vacuum chamber in the vacuum film formation, and are peeled off to adhere to the magnetic recording media to cause defects. Further, to replace the substrate rolls in the apparatuses of above published prior arts, the vacuum chamber has to be opened to atmospheric pressure. When the vacuum chamber is opened to atmospheric pressure, the surface of the film deposited inside the vacuum chamber adsorbs moisture and oxygen in the air and thereby suffers from physicochemical changes. As a result of repetition of evacuation and opening to atmospheric pressure, the film attached inside the vacuum chamber tends to be easily peeled off and adhere to the magnetic recording medium as defects. Thus, such apparatuses need cleaning of the vacuum chamber each time production of a long magnetic material finishes or at a certain production interval, resulting in poor productivity.

In high density magnetic recording media, it is required to minimize the thickness of a protective layer, thereby reducing magnetic spacing between a magnetic layer and a magnetic head. Therefore, the protective layer is required to have sufficient hardness and abrasion resistance even with an ultra-small thickness. Films of diamond-like carbon (DLC) are preferred protective layers meeting such requirements, which can be formed by plasma CVD or ion beam deposition using gas materials containing hydrocarbons, ECR sputtering or ECR-CVD using high density plasma, or filtered cathodic vacuum arc (FCVA) coating using arc discharge. Though such diamond-like carbon films exhibit desired characteristics on the media, a film deposited on a vacuum chamber is easily peeled off and causes defects because of its large film stress. Also from this viewpoint, venting the vacuum chamber to the atmosphere is unfavorable.

The hydrocarbon gases used in plasma CVD, etc. have to be evacuated by a turbomolecular pump because sufficient hydrogen gas evacuation cannot be secured with a cryopump, which is commonly employed in apparatuses for producing the magnetic recording media, In the apparatus described in JP-A-5-274659, the vacuum is divided by a partition and the divided parts have the same vacuum system, so that the protective layer is limited to a carbon film formed by sputtering using Ar gas. In the apparatus described in JP-A-7-235035, a protective layer is formed by plasma CVD, and a magnetic layer forming chamber and a protective layer forming chamber share the same vacuum system, whereby there is a possibility that impurity gases, especially hydrogen-containing gases may enter the magnetic layer forming chamber. The impurity gases in the magnetic layer forming system adversely affect the magnetic characteristics of the resulting magnetic recording medium, and thus it is unfavorable to form the magnetic layer and the protective layer in the film forming chambers using the same vacuum system.

To obtain the high density recording media, it is necessary to provide various underlayers by sputtering to improve the characteristics of the magnetic layer. The various underlayers have various functions of control of magnetic layer crystal orientation, separation of magnetic particles, magnetic particle size control, etc., and the conditions for forming the underlayers should be optimized so that the underlayers may perform the functions to the full. Particularly the types and pressures of gases for forming the underlayers are factors heavily influencing the characteristics of the resulting layers, and optimal ones are often different between the underlayers. In JP-A-5-274659, JP-A-7-235035 and JP-A-2002-367149, though methods of forming magnetic layers with monolayer structures basically by vapor deposition are described in detail, methods of forming film stacks by sputtering are not sufficiently described. In Examples given in the references, a single vacuum evacuation system is used, which necessitates passing the substrate through the chamber as many times as the number of the layers to be stacked. Not only production costs but also defects are remarkably increased due to the increase of the number of passes.

JP-B-61-36862 and JP-A-9-230538 disclose methods for continuously leading a substrate from an atmospheric pressure into a reduced pressure, thereby continuously producing a long magnetic material without opening the film forming chamber to atmospheric pressure. Production of high density magnetic recording media demands creation of a vacuum having high degree and quality in film forming chamber. However, in the methods disclosed in JP-B-61-36862 and JP-A-9-230538, it is difficult to secure a high vacuum degree constantly and an impurity gas in the air is inevitably incorporated into the vacuum film forming chamber. Therefore, it is very difficult to stably produce the high density magnetic recording media by the methods. Furthermore, in the methods, the flexible polymer substrate is conveyed through a vacuum separation and highly pressed by a seal roll therein, whereby the magnetic layer is apt to suffer from scratches or pressure marks, making it difficult to produce a highly reliable magnetic recording medium.

Further, in the case of using a CoPtCr-based magnetic layer and a Cr alloy underlayer, which are commonly used in hard disks, the substrate temperature has to be 200° C. or higher and thereby the polymer film is thermally damaged and unpractical. Though a proposal has been made on using a highly heat-resistant film of a polyimide or an aromatic polyamide as the polymer film, it is difficult to put such a heat-resistant film into practical use because of the large cost.

In contrast, in the case of using an Ru underlayer and a magnetic layer of a ferromagnetic metal thin film containing a ferromagnetic metal alloy and a nonmagnetic oxide, even when the magnetic layer is formed at room temperature, the resultant magnetic layer has magnetic characteristics equal to those of a CoPtCr-based magnetic layer formed at a high temperature of 200 to 500° C. The magnetic layer of the ferromagnetic metal thin film containing the ferromagnetic metal alloy and the nonmagnetic oxide may have a granular structure. However, also in this case, the substrate is exposed to plasma in the step of forming the protective layer by sputtering or plasma CVD, so that the substrate is thermally deformed in some cases. Particularly inexpensive polyester-based polymer films using polyethylene terephthalate, polyethylene naphthalate, etc. disadvantageously have low glass transition temperatures to cause the deformation of the substrate.

Methods of bringing a substrate into close contact with a can drum to prevent the substrate deformation have been studied as described in JP-A-2002-197633. However, the methods are insufficient for using a substrate of polyethylene terephthalate, polyethylene naphthalate, etc. with a low glass transition temperature and for reducing the substrate deformation to the level required for high density recording.

Recordable and rewritable optical disks represented by DVD-Rs/RWs are excellent in exchangeability and widespread because they do not come near heads as magnetic disk. However, in view of the thickness of an optical pickup and cost, the optical disks have difficulty in taking on a double-sided disk structure as with magnetic disks, which structure is advantageous for increasing recording capacity. Additionally, the optical disks have lower surface recording densities and lower data transfer rates as compared with the magnetic disks, and thus cannot have sufficient performance for use as rewritable, large-capacity recording media,

### SUMMARY OF THE INVENTION

The present invention has been accomplished in the light of the above problems. An object of the invention is to provide a process and an apparatus for producing a magnetic recording medium with markedly reduced defects and excellent production suitability such that a chamber for forming a magnetic layer, etc. is not opened to atmospheric pressure to maintain the vacuum state thereof even in the step of replacing a roll.

Another object of the invention is to provide a process and an apparatus for producing a magnetic recording medium, which can prevent deformation of a substrate due to heat generated in film formation and can produce a magnetic recording medium having high recording density, large capacity, and high reliability like hard disks at low cost.

According to a first aspect of the present invention, there is provided a process for producing a magnetic recording medium comprising the steps of unrolling a flexible polymer substrate from a feed roll, forming a magnetic layer on at least one side of the flexible polymer substrate by a vacuum film forming method in a film forming chamber, and taking up the flexible polymer substrate on a take-up roll, wherein the feed roll and/or the take-up roll being replaced while maintaining the vacuum state for forming the magnetic layer in the film forming chamber.

For example when the feed roll and/or the take-up roll are replaced, the film forming chamber is not opened to atmospheric pressure to maintain the vacuum state. Thus, for example, the substrate is unrolled from the feed roll, at least the magnetic layer is formed on the one side of the unrolled substrate in the film forming chamber, and the resultant is taken up on the take-up roll as a long sample. The take-up roll may be removed and attached as a feed roll while maintaining the vacuum state in the film forming chamber. Then, a long magnetic recording medium or magnetic recording material may be obtained by the steps of unrolling the sample from the feed roll, forming at least a magnetic layer on the other side of the unrolled sample in the film forming chamber, and taking up the resultant on a take-up roll.

The film forming chamber is not opened to atmospheric pressure to maintain the vacuum state in the step of replacing the feed roll and/or the take-up roll in this manner, so that an attached film (e.g., a sputter film) deposited inside the film forming chamber is protected from contamination with the air in the production. Further, the attached film hardly peels off and is thus prevented from adhering to the magnetic recording medium (or the magnetic recording material), whereby defects due to the adhesion are markedly reduced in the medium.

Further, the interval of cleaning (maintenance) of the film forming chamber can be lengthened, and the evacuation time of the film forming chamber can be greatly reduced, thereby resulting in remarkably improved productivity. Additionally, since the atmosphere in the film forming chamber is maintained constant, a layer with desired film qualities can be stably formed on the substrate to improve the qualities of the magnetic recording medium.

In the first aspect of the invention, a vacuum separator for selectably connecting and closing the film forming chamber and a roll chamber containing the feed roll and the take-up roll may be placed between the chambers, and the feed roll and/or the take-up roll may be replaced while closing the roll chamber and the film forming chamber by the vacuum separator.

In this case, the vacuum separator may comprise a first shutter and a second shutter between the roll chamber and the film forming chamber. When the shutters are closed, the first shutter presses a portion of the flexible polymer substrate unrolled from the feed roll and the second shutter presses a portion to be taken up on the take-up roll. The feed roll and/or the take-up roll may be replaced after the first and second shutters are closed to press the flexible polymer substrate.

The first shutter may comprise a first rigid member and a first elastic member that is selectably moved or deformed toward an end of the first rigid member, and the second shutter may comprise a second rigid member and a second elastic member that is selectably moved or deformed toward an end of the second rigid member. The feed roll and/or the take-up roll may be replaced after the first and second shutters are closed, the first elastic member is moved or deformed toward the end of the first rigid member, and the second elastic member is moved or deformed toward the end of the second rigid member, to press the flexible polymer substrate.

According to a second aspect of the invention, there is provided a process for producing a magnetic recording medium comprising forming a magnetic layer on at least one side of a flexible polymer substrate, wherein at least the magnetic layer being formed on the flexible polymer substrate by a vacuum film forming method while bringing the flexible polymer substrate into close contact with a film forming roll having a controlled surface temperature within a predetermined temperature range.

Thus, the process can provide a magnetic recording medium having a high recording density, large capacity, and high reliability like hard disks at low cost while preventing deformation of the substrate due to heat generated in the film formation, etc.

In the second aspect of the invention, after forming the magnetic layer, a protective layer may be formed on the magnetic layer while bringing the flexible polymer substrate into close contact with the film forming roll having the controlled surface temperature within the predetermined temperature range.

Further, in the second aspect of the invention, the surface temperature of the film forming roll is preferably controlled within a range of (a predetermined temperature ±10° C.), which is preferably (the predetermined temperature ±5° C.), more preferably (the predetermined temperature ±2° C.).

The predetermined temperature is preferably selected from the range of −20° C. to +40° C.

Further, it is preferred that the temperature of the film forming roll is controlled by circulating a refrigerant inside the roll at a flow rate of 3 L/minute or more.

The second aspect of the invention shows advantageous effect particularly in a case where the flexible polymer substrate comprises polyethylene terephthalate or polyethylene naphthalate, and the magnetic layer is a granular magnetic layer.

Thus, in a case where polyethylene terephthalate or polyethylene naphthalate is used for the substrate and the vacuum film formation is carried out on the film forming roll having a surface temperature of −20 to 40° C. controlled within ±2° C., a flat magnetic tape or flexible disk resistant to magnetic head contact recording can be provided at low cost by using the polyester-based, inexpensive, flexible polymer substrate. Generally, in a case of forming a magnetic layer on a polyester-based substrate by a vacuum film forming method, the substrate is often deformed to cause cracks and stripes on the resultant magnetic recording medium. In the second aspect of the invention, the temperature of the substrate is stably controlled at low temperature on the film forming roll, whereby deformation of the substrate can be prevented in formation of the granular magnetic layer and the magnetic recording medium can show stable magnetic characteristics due to the fixed substrate temperature.

According to a third aspect of the invention, there is provided an apparatus for producing a magnetic recording medium comprising a vacuum chamber, which comprises a roll chamber containing a feed roll with a flexible polymer substrate wound and a take-up roll for taking up a treated flexible polymer substrate, a film forming chamber for forming a magnetic layer on at least one side of the flexible polymer substrate unrolled from the feed roll, and a vacuum separator capable of selectably connecting and closing the roll chamber and the film forming chamber to maintain the vacuum state in the film forming chamber even after the roll chamber is opened.

Thus, the film forming chamber for forming the magnetic layer, etc. is not opened to atmospheric pressure to maintain the vacuum state even in replacement of the rolls, whereby the magnetic recording medium can be produced using the apparatus with markedly reduced defects and excellent production suitability.

In the third aspect of the invention; the film forming chamber may comprise a film forming section for forming the magnetic layer and a film forming section for forming a protective layer on the magnetic layer, and a gas mixing reducing member may be disposed between each adjacent film forming sections to reduce gas penetration.

Further, the vacuum separator may comprise a first shutter and a second shutter between the roll chamber and the film forming chamber. The first shutter is closed to press a portion of the flexible polymer substrate unrolled from the feed roll and the second shutter is closed to press a portion to be taken up on the take-up roll. The first shutter and the second shutter are closed and press the flexible polymer substrate to maintain the vacuum state in the film forming chamber even after the roll chamber is opened.

In this case, the first shutter may comprise a first rigid member and a first elastic member that is selectably moved or deformed toward an end of the first rigid member, and the second shutter may comprise a second rigid member and a second elastic member that is selectably moved or deformed toward an end of the second rigid member. The flexible polymer substrate may be pressed such that the first and second shutters are closed, the first elastic member is moved or deformed toward the end of the first rigid member, and the second elastic member is moved or deformed toward the end of the second rigid member.

It is preferred that the first and second rigid members each have a Young's modulus of 7×10¹⁰ Pa or more and a maximum surface roughness Rz of 0.4 μm or less, the first and second elastic members each have a standard hardness (JIS K6253, type A durometer) of 50° or more, and the first and second elastic members apply a pressure of 0.3 MPa or more to the first and second rigid members when the first and second shutters are closed.

Further, it is preferred that the apparatus comprises a vacuum evacuation system for controlling vacuum degrees of the roll chamber and the film forming chamber at 1.0×10⁻⁴ Pa or less, preferably 5×10⁻⁵ Pa or less, and the vacuum degree of the film forming chamber is maintained at 1×10⁻¹ Pa or less when the roll chamber is opened from the vacuum state.

According to a fourth aspect of the invention, there is provided an apparatus for producing a magnetic recording medium by forming at least a magnetic layer on at least one side of a flexible polymer substrate, the apparatus comprising a film forming unit for forming at least the magnetic layer on the flexible polymer substrate by a vacuum film forming method while bringing the flexible polymer substrate into close contact with a film forming roll, and a temperature control unit for controlling the surface temperature of the film forming roll within a predetermined temperature range.

Thus, the substrate deformation due to heat generated in the film formation, etc. can be prevented, and a magnetic recording medium having high recording density, large capacity, and high reliability like hard disks can be produced at low cost.

In the fourth aspect of the invention, the film forming unit may be such that, after forming the magnetic layer, a protective layer is formed on the magnetic layer while bringing the flexible polymer substrate into close contact with the film forming roll.

The temperature control unit preferably controls the surface temperature of the film forming roll within a range of (a predetermined temperature ±10° C.), preferably (the predetermined temperature ±5° C.), more preferably (the predetermined temperature ±2° C.).

The predetermined temperature is preferably selected from the range of −20° C. to +40° C.

A channel in which a refrigerant can be circulated may be formed inside the film forming roll. In this case, the channel for circulating the refrigerant preferably comprises a spiral channel along an outer circumference surface of the film forming roll. Further, at least part of the channel is preferably placed at 50 mm or less from the surface of the film forming roll in the depth direction.

The surface of the film forming roll preferably comprises a material having a specific heat of 0.5 J/g·K or less. In this case, the surface of the film forming roll may comprise at least one material selected from the group consisting of stainless steels, copper, and aluminum, and the surface may be subjected to a hard chrome plating treatment.

Further, the film forming roll preferably has a diameter of 350 mm or more, and the film forming roll preferably has a maximum surface roughness of 0.1 μm or less.

As described above, the process and apparatus for producing a magnetic recording medium according to the present invention can produce a magnetic recording medium with excellent production suitability such that the film forming chamber for forming the magnetic layer, etc. is not opened to atmospheric pressure even while replacing the roll to maintain the vacuum state, thereby remarkably reducing defects on the magnetic recording medium.

Further, by the process and apparatus for producing a magnetic recording medium according to the present invention, the substrate can be prevented from being deformed due to heat generated in film formation, etc., and a highly reliable magnetic recording medium having high recording density and large capacity like hard disks can be produced at low cost.

### BRIEF DESCRIPTION OF THE DRAWINGS

FIG. 1 is a cross sectional view showing a part of a magnetic recording medium obtained by the process or apparatus of the present invention.

FIG. 2 is a schematic view showing structure of an apparatus according to the first embodiment.

FIG. 3 is a perspective view showing a part of a channel formed in a film forming roll for circulating a refrigerant.

FIG. 4 is an explanatory view showing an example of structure of first and second shutters in a vacuum separator.

FIG. 5 is an explanatory view showing another example of structure of first and second shutters in a vacuum separator.

FIGS. 6A to 6D are each an explanatory view showing a cross-sectional shape of a portion of a first rigid member facing a first elastic member.

FIG. 7 is a schematic view showing structure of an apparatus according to the second embodiment.

FIG. 8 is a schematic view showing structure of an apparatus according to the third embodiment.

FIG. 9 is a table showing results of magnetic characteristics evaluation of Examples 1 to 8 and Comparative Examples 1 to 5 in a first experiment example.

FIG. 10 is a table showing results of defect evaluation of Examples 1 to 8 and Comparative Examples 1 to 5 in the first experiment example.

FIG. 11 is a table showing results of running durability evaluation of Examples 1 to 8 and Comparative Examples 1 to 5 in the first experiment example.

FIG. 12 is a table showing results of evaluating magnetic characteristics, substrate deformation, and running durability in Examples 11 to 14 and Comparative Examples 11 to 13 in a second experiment example.

### DETAILED DESCRIPTION OF THE INVENTION

The process and apparatus for producing a magnetic recording medium according to the present invention will be described in detail based on its preferred embodiments with reference to the accompanying drawings.

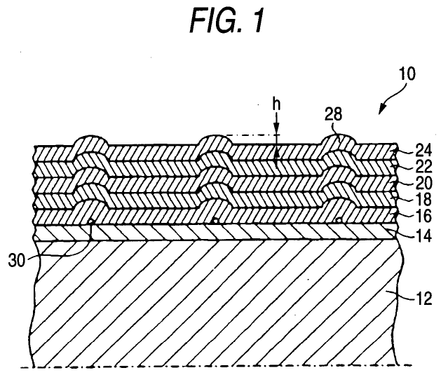

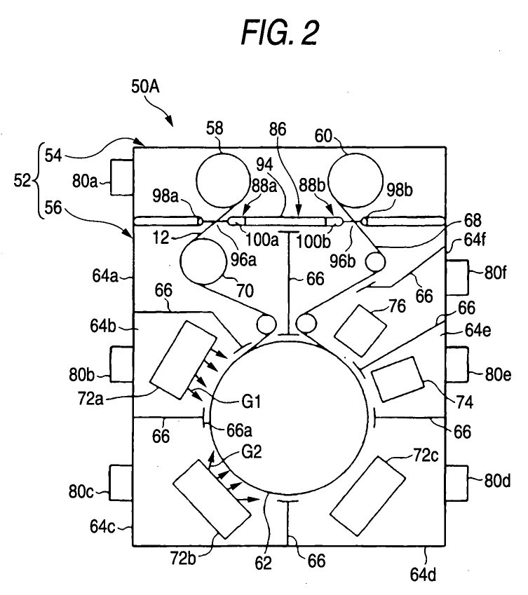

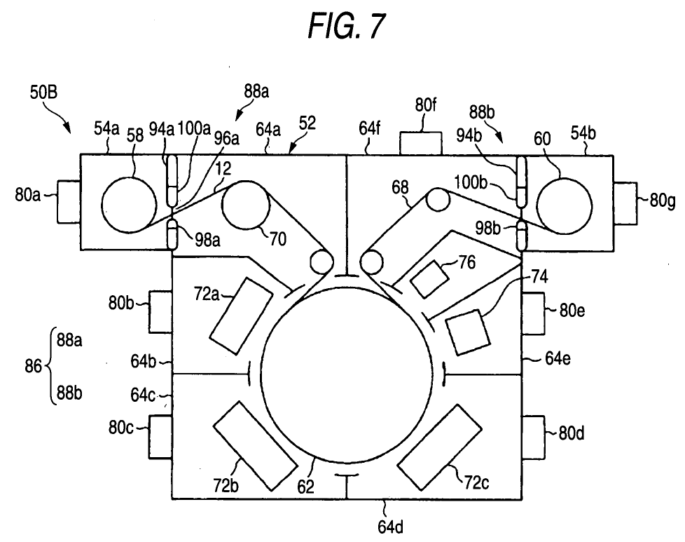

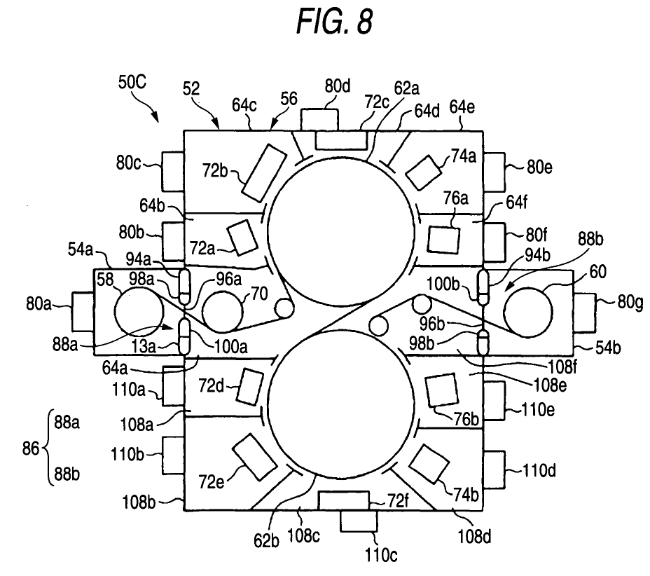

A magnetic recording medium 10 shown in FIG. 1, which is produced by a process according to this embodiment, an apparatus 50A shown in FIG. 2 according to a first embodiment, an apparatus 50B shown in FIG. 7 according to a second embodiment, or an apparatus 50C shown in FIG. 8 according to a third embodiment, may be a flexible disk or a magnetic tape. Thus, the magnetic recording medium 10 is referred to as the flexible disk 10 or the magnetic tape 10 below in some cases.

The flexible disk 10 has a center hole and held in a plastic cartridge. The cartridge generally has an access opening covered with a metal shutter, and a magnetic head is introduced through the access opening, whereby signals are recorded and reproduced on the flexible disk 10.

FIG. 1 is a cross sectional view showing a preferred layer structure of the flexible disk 10 removed from the cartridge. The flexible disk 10 has a film-shaped flexible polymer substrate 12 (hereinafter referred to as the substrate 12), and has an undercoating layer 14 having surface projections, a first underlayer 16, a second underlayer 18, a magnetic layer 20, a protective layer 22, and a lubricant layer 24 formed in this order on each side of the substrate 12. For use as a perpendicular magnetic recording medium, it is preferred that a soft magnetic layer (not shown) is formed between the substrate 12 and the magnetic layer 20. The flexible disk 10 usually has a catching part (not shown) in its center to be attached to a flexible disk drive.

The magnetic tape 10 has a long tape shape formed by slitting a magnetic material, and is packaged in an open reel or reel cartridge of a plastic, etc. Signals are recorded or reproduced when the magnetic tape 10 unrolled from the reel cartridge passes through a magnetic head portion.

Magnetic tape is a flexible polymer film substrate of strip form having formed on one side thereof at least a magnetic layer. The magnetic tape 10 has a tape-shaped substrate of a flexible polymer film and at least the magnetic layer formed on one side thereof, and as described above, the undercoating layer 14, the first underlayer 16, the second underlayer 18, the magnetic layer 20, the protective layer 22, and the lubricant layer 24 are preferably formed in this order. The magnetic tape 10 is unrolled from the reel cartridge, conveyed, and passes through a guide roll, and the opposite side of the magnetic tape 10 is brought into contact with the guide roll in the conveyance. It is preferred that a backcoating layer of carbon, etc. is formed on the opposite side to smoothly convey the magnetic tape 10.

The apparatus 50A according to the first embodiment, which is suitable for the process, will be described with reference to FIGS. 2 to 6D.

As shown in FIG. 2, the apparatus 50A according to the first embodiment has a vacuum chamber 52. The vacuum chamber 52 contains a roll chamber 54 and a film forming chamber 56.

The roll chamber 54 contains a feed roll 58 with the long substrate 12 wound and a take-up roll 60. The substrate 12 wound on the feed roll 58 is coated with the undercoating layer 14 previously as shown in FIG. 1.

The film forming chamber 56 contains a cylindrical film forming roll 62, which is supported rotatably by the vacuum chamber 52 to convey the long substrate 12 along the surface thereof. And the film forming chamber 56 contains, for example, 6 vacuum sections (a first vacuum section 64a, a second vacuum section 64b, a third vacuum section 64c, a fourth vacuum section 64d, a fifth vacuum section 64e, and a sixth vacuum section 64f) placed around the film forming roll 62. The first to sixth vacuum sections 64a to 64f are separated by partitions 66 respectively.

The roll of the film substrate 12 is unrolled from the feed roll 58 in the roll chamber 54 and introduced to the film forming chamber 56, the first underlayer 16 is formed on the substrate 12 conveyed along the film forming roll 62 in the second vacuum section 64b, and then the second underlayer 18, the magnetic layer 20, and the protective layer 22 are formed in this order respectively in the third vacuum section 64c, the fourth vacuum section 64d, and the sixth vacuum section 64f while rotating the film forming roll 62, and the resultant is taken up on the take-up roll 60 in the roll chamber 54, so that a long film (a magnetic recording material 68) having the magnetic layer 20, etc. is produced.

The first vacuum section 64a has a heating roll 70 for heating the substrate 12 introduced from the feed roll 58. Gases contained in the substrate 12 can be removed by heating the substrate 12. A heater may be formed between the feed roll 58 and the film forming roll 62 instead of the heating roll 70. The heating may be carried out by the film forming roll 62 without forming the heating roll 70.

A first sputtering unit 72a, a second sputtering unit 72b, and a third sputtering unit 72c facing the film forming roll 62 are placed respectively in the second vacuum section 64b, the third vacuum section 64c, and the fourth vacuum section 64d. The first to third sputtering units 72a to 72c each contain a sputtering cathode as a discharging means, and a target for forming a desired film.

An argon ion gun 74 is placed in the fifth vacuum section 64e (a glow treatment section). The magnetic layer 20 may be irradiated with an argon plasma and glow-treated by the argon ion gun 74, to improve the adhesion between the protective layer 22 and the magnetic layer 20.

The sixth vacuum section 64f contains a protective layer forming gun 76. The protective layer forming gun 76 may be a plasma CVD gun capable of forming a rigid carbon film by the steps of introducing a hydrocarbon gas to a reactor tube, applying a coil magnetic field to generate a high density plasma, and applying a bias voltage to the substrate 12 to generate positive carbon ions, an ion beam gun capable of forming a rigid carbon film by the steps of introducing a hydrocarbon gas to an ion source, applying a magnetic field and an electric field to generate a high density plasma, and pushing out positive carbon ions generated due to decomposition by the powerful positive electric field, an ECR sputter source capable of generating high density plasma, a filtered cathodic vacuum arc (FCVA) gun capable of extracting high purity carbon ions by arc discharge, etc. Preferred of them are the plasma CVD gun and the ion beam gun capable of forming a hydrogenated diamond-like carbon film, i.e., a DLC protective layer having both of film hardness and sliding characteristics. The sixth vacuum section 64f may have a plurality of the protective layer forming guns 76.

Further, the roll chamber 54 and the first vacuum section 64a, and the second to sixth vacuum sections 64b to 64f have an independent vacuum evacuation system (a vacuum pump) 80a, 80b, 80c, 80d, 80e, and 80f respectively, the roll chamber 54 and the first to sixth vacuum sections 64a to 64f can be evacuated independently. The roll chamber 54 and the first to sixth vacuum sections 64a to 64f can be independently evacuate by the vacuum evacuation systems into a vacuum state of 1.0×10⁻⁴ Pa or less, preferably 5.0×10⁻⁵ Pa or less.

Further, the roll chamber 54 and the first to sixth vacuum sections 64a to 64f each have a gas flow valve and a gas pressure monitor (not shown).

Thus, the vacuum evacuation systems of the roll chamber 54 and the first to sixth vacuum sections 64a to 64f are independent from each other, whereby the gas type, gas pressure, etc. in the first to sixth vacuum sections 64a to 64f can be independently selected, and the optimum film formation conditions can be achieved to obtain desired characteristics. In the case of forming a layer extremely susceptible to an impurity gas in the vacuum sections, the layer is preferably formed in a purer gas atmosphere by, for example, providing a differential pressure section between the adjacent sections.

For example, in the fourth vacuum section 64d (the magnetic layer forming chamber), which is adversely affected by moisture in the atmosphere, it is preferred to use an evacuation system including a cryopump as a main pump effective to remove the moisture.

In a case where a hydrocarbon-containing gas is introduced to the sixth vacuum section 64f to form a hydrogenated diamond-like carbon film, i.e., a DLC protective layer 22, by plasma CVD, ion beam deposition, etc., it is preferred to use an evacuation system including a turbomolecular pump as a main pump because a cryopump generally used for forming the magnetic layer 20 in the fourth vacuum section 64d is insufficient in evacuation amount.

Various transfer rolls disposed in the roll chamber 54 and the film forming chamber 56 may be appropriately surface-treated to convey the substrate 12 without causing a wrinkle or a scratch. For example, metal transfer rolls are preferably hard chrome-plated and mirror-polished, and the maximum surface roughness Rz is preferably 0.8 μm or less, more preferably 0.4 μm or less. When the transfer rolls have the surface roughness Rz of 0.8 μm or less, even in the case of bringing the smooth substrate 12 into close contact with the rolls, a magnetic recording medium with surface smoothness can be produced without transferring the surface roughness of the rolls to the medium. In this embodiment, the maximum surface roughness (Rz) is a value obtained in accordance with JIS B0601-2001.

The surface temperature of the film forming roll 62 is controlled within a predetermined temperature range. For example, the surface temperature of the film forming roll 62 is controlled within a range of (a predetermined temperature ±10° C.), preferably (the predetermined temperature ±5° C.), more preferably (the predetermined temperature ±2° C.) by a chiller unit (not shown), etc. In this case, the predetermined temperature may be selected from the range of −20° C. to 40° C.

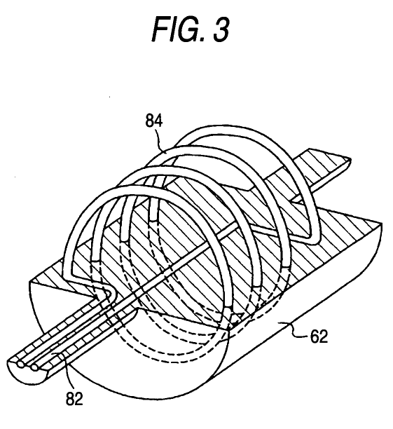

There are no particular restrictions on a method for controlling the surface temperature. For example, a channel 82 which a refrigerant is circulated in may be formed inside the film forming roll 62 as shown in FIG. 3 to control the surface temperature. In FIG. 3, the upper half of the body of the film forming roll 62 is omitted to show the inside of the film forming roll 62 clearly.

In this example, the channel 82 for circulating the refrigerant comprises a spiral channel 84 along an outer circumference surface of the film forming roll 62. The surface of the film forming roll 62 is exposed to plasma through the substrate, whereby at least part of the spiral channel 84 in the channel 82 for circulating the refrigerant is preferably placed at 50 mm or less from the surface in the depth direction (the radial direction), and is more preferably placed at 30 mm or less therefrom. The refrigerant may be cooling water, ethylene glycol, etc.

Further, the surface of the film forming roll 62 preferably comprises a material having a large heat conductivity to easily cool the substrate 12. The specific heat of the material is preferably 0.5 J/g·K or less, further preferably 0.45 J/g·K or less. Examples of such materials include stainless steels, copper, and aluminum. The surface of the film forming roll 62 is preferably hard chrome-plated.

The maximum surface roughness Rz of the film forming roll 62 is preferably 0.1 μm or less, 0.05 μm or less. When the film forming roll 62 has such a smooth surface, the substrate 12 is not adversely affected by the surface roughness of the roll 62. Additionally, the adhesion of the roll 62 to the substrate 12 is also improved in this case, whereby misalignment of the substrate 12 can be prevented during transfer, and the defects on the magnetic recording medium 10 can be reduced. Methods for controlling the maximum surface roughness of the film forming roll 62 within the above range include a method of subjecting the surface of the roll 62 to hard chrome plating and mirror polishing.

The weight of the film forming roll 62 is preferably 300 kg or more, more preferably 400 kg or more. As the weight is increased, the heat capacity of the film forming roll 62 is increased to reduce the temperature change.

The film forming roll 62 preferably has a certain level of a size not only to bring the substrate 12 into close contact with the roll 62, thereby preventing the misalignment, but also to make the substrate 12 face the first to third sputtering units 72a to 72c. The diameter of the film forming roll 62 is preferably 250 mm or more, more preferably 400 mm or more.

In the apparatus 50A according to the first embodiment, a vacuum separator 86 for selectably connecting and closing the roll chamber 54 and the film forming chamber 56 is disposed between the chambers 54 and 56, and the feed roll 58 and/or the take-up roll 60 can be replaced while closing the roll chamber 54 and the film forming chamber 56 by the vacuum separator 86.

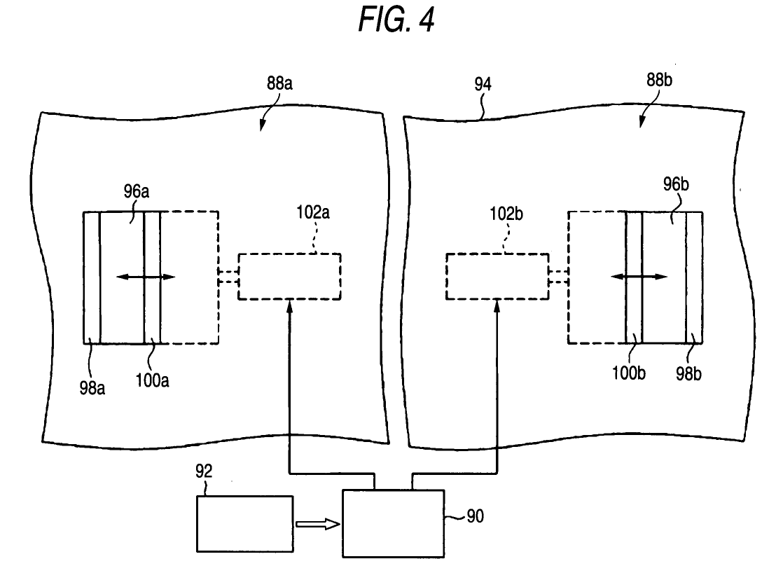

As shown in FIG. 2, the vacuum separator 86 comprises a first shutter 88a, a second shutter 88b, and a control unit 90 (see FIG. 4) for controlling opening and closing of the shutters 88a and 88b. The control unit 90 is connected to an input device 92 (see FIG. 4), and users can input an order of Open or Close of the first and second shutters 88a and 88b from the input device 92 into the control unit 90.

The first shutter 88a, which is placed between the roll chamber 54 and the film forming chamber 56, is closed to press a portion of the substrate 12 unrolled from the feed roll 58. The second shutter 88b, which is placed between the roll chamber 54 and the film forming chamber 56, is closed to press a portion of the substrate 12 to be taken up on the take-up roll 60.

For example, as shown in FIG. 4, a partition 94 is formed at the boundary of the roll chamber 54 and the film forming chamber 56, and the partition 94 comprises a first opening 96a which the substrate 12 unrolled from the feed roll 58 passes through and a second opening 96b which the substrate 12 to be wound on the take-up roll 60 passes through.

For example, a first rigid member 98a is disposed on the left inner wall of the first opening 96a, and a first elastic member 100a, which is selectably moved or deformed toward an end of the first rigid member 98a, is disposed on the right inner wall. In the same manner a second rigid member 98b is disposed on the right inner wall of the second opening 96b, and a second elastic member 100b, which is selectably moved or deformed toward an end of the second rigid member 98b, is disposed on the left inner wall.

The first and second elastic members 100a and 100b may be selectably moved or deformed toward the end of the first and second rigid members 98a and 98b in the following manner respectively.

For example, as shown in FIG. 4, the first and second elastic members 100a and 100b are solid, a first reciprocating unit 102a such as an air cylinder for reciprocating the first elastic member 100a toward the first rigid member 98a and a second reciprocating unit 102b such as an air cylinder for reciprocating the second elastic member 100b toward the second rigid member 98b are provided between the first and second openings 96a and 96b in the partition 94, and a guide rail or a guide groove (not shown) is formed on each of the upper and lower inner walls of the first and second openings 96a and 96b.

In this case, the first shutter 88a comprises the first rigid member 98a, the first elastic member 100a, and the first reciprocating unit 102a, and the second shutter 88b comprises the second rigid member 98b, the second elastic member 100b, and the second reciprocating unit 102b.

When the order of Open is input by the input device 92 into the first and second shutters 88a and 88b, the control unit 90 Open-controls the first and second reciprocating units 102a and 102b (opens the first and second openings 96a and 96b) to move the first and second elastic members 100a and 100b. Thus, the first rigid member 98a and the first elastic member 100a recede from each other, and also the second rigid member 98b and the second elastic member 100b recede from each other, whereby the first and second openings 96a and 96b are opened. Obviously the first and second openings 96a and 96b can be independently opened.

When the order of Close is input by the input device 92 into the first and second shutters 88a and 88b, the control unit 90 Close-controls the first and second reciprocating units 102a and 102b (closes the first and second openings 96a and 96b) to move the first and second elastic members 100a and 100b. Thus, the first elastic member 100a approaches and contacts the first rigid member 98a, and also the second elastic member 100b approaches and contacts the second rigid member 98b, whereby the first and second openings 96a and 96b are closed. In a case where the substrate 12 is placed in the first and second openings 96a and 96b, a portion of the substrate 12 in the first opening 96a is pressed by the first rigid member 98a and the first elastic member 100a, and a portion of the substrate 12 in the second opening 96b is pressed by the second rigid member 98b and the second elastic member 100b. Obviously the first and second shutters 88a and 88b can be independently closed.

Though the first and second reciprocating units 102a and 102b are placed in the partition 94 in the above example, the units 102a and 102b may be placed outside the partition 94 such that a linking unit is placed in the partition 94 to transfer driving forces of the units 102a and 102b.

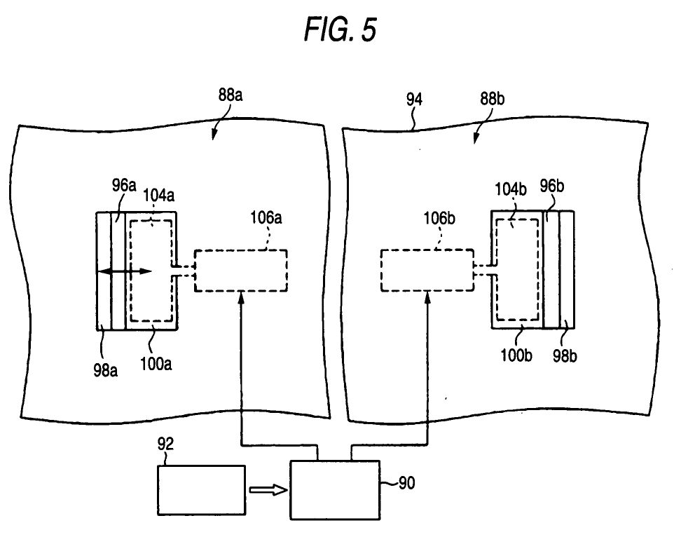

For example as shown in FIG. 5, the first and second elastic members 100a and 100b may have hollow portions 104a and 104b respectively, and the first and second elastic members 100a and 100b may be expanded and deformed by filling the hollow portions 104a and 104b with a fluid such as air. In this case, first and second pump units 106a and 106b are provided between the first and second openings 96a and 96b in the partition 94, and the fluid is charged into and discharged (evacuated) from the hollow portion 104a of the first elastic member 100a and the hollow portion 104b of the second elastic member 100b by the first and second pump units 106a and 106b.

In this case, the first shutter 88a comprises the first rigid member 98a, the first elastic member 100a, and the first pump unit 106a, and the second shutter 88b comprises the second rigid member 98b, the second elastic member 100b, and the second pump unit 106b.

When an order of Open is input into the first and second shutters 88a and 88b by the input device 92, the control unit 90 Open-controls the first and second pump units 106a and 106b, so that the fluid is discharged (evacuated) from the hollow portion 104a of the first elastic member 100a and the hollow portion 104b of the second elastic member 100b. Thus, the first and second elastic members 100a and 100b are shrunk and deformed, the first rigid member 98a and the first elastic member 100a recede from each other, the second rigid member 98b and the second elastic member 100b recede from each other, and the first and second openings 96a and 96b are both in the open state. Obviously the openings 96a and 96b can be independently converted to the open state.

When an order of Close is input into the first and second shutters 88a and 88b by the input device 92, the control unit 90 Close-controls the first and second pump units 106a and 106b, and the hollow portion 104a of the first elastic member 100a and the hollow portion 104b of the second elastic member 100b are filled with the fluid. Thus, the first and second elastic members 100a and 100b are expanded and deformed, the first elastic member 100a approaches and contacts the first rigid member 98a, the second elastic member 100b approaches and contacts the second rigid member 98b, and the first and second openings 96a and 96b are both in the closed state. In a case where the substrate 12 is placed in the first and second openings 96a and 96b, the first rigid member 98a and the first elastic member 100a press the portion of the substrate 12 placed in the first opening 96a and the second rigid member 98b and the second elastic member 100b press the portion of the substrate 12 placed in the second opening 96b. Obviously the first and second shutters 88a and 88b can be independently converted to the closed state.

Though the first and second pump units 106a and 106b are placed in the partition 94 in the above example, the units 106a and 106b may be placed outside the partition 94 or outside the vacuum chamber 52 such that a pipe is provided from the units 106a and 106b to the partition 94.

In the closed state of the first shutter 88a, the pressure of the first elastic member 100a on the first rigid member 98a is 0.3 MPa or more, preferably 0.4 MPa or more. Also the pressure of the second elastic member 100b on the second rigid member 98b is 0.3 MPa or more, preferably 0.4 MPa or more, in the closed state of the second shutter 88b.

The vacuum state of the first to sixth vacuum sections 64a to 64f in the film forming chamber 56 can be maintained in the above manner even when the substrate 12 is placed between the first rigid member 98a and the first elastic member 100a and between the second rigid member 98b and the second elastic member 100b. Thus, by closing the first and second shutters 88a and 88b, the vacuum degree of the film forming chamber 56 can be 1×10⁻¹ Pa or less even when the roll chamber 54 is opened under atmospheric pressure to replace the feed roll 58 and/or the take-up roll 60.

The Young's modulus of the first and second rigid members 98a and 98b are preferably 7×10¹⁰ Pa or more, more preferably 1×10¹¹ Pa or more, and the maximum surface roughnesses Rz of the first and second rigid members 98a and 98b is preferably 1.0 μm or less, more preferably 0.4 μm or less. Further, the hardnesses of the first and second elastic members 100a and 100b is preferably standard hardness 50° or more (JIS K6253, type A durometer), more preferably 55° or more.

Specific examples of materials for the first and second rigid members 98a and 98b include iron, stainless steels, and titanium, and specific examples of materials for the first and second elastic members 100a and 100b include silicone rubbers, NBRs, and fluororubbers.

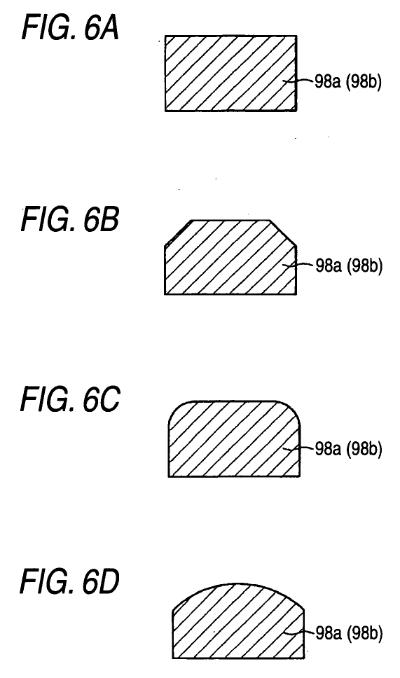

In the first rigid member 98a, the shape, particularly the cross sectional shape, of a portion facing the first elastic member 100a may be a rectangular shape shown in FIG. 6A, a shape with chamfered corners shown in FIG. 6B, a partially curved shape with a flat contact surface for the substrate 12 and the first elastic member 100a shown in FIG. 6C, or a entirely curved shape shown in FIG. 6D. The shapes of FIGS. 6C and 6D do not damage the substrate 12, and thereby are more preferred. The same is equally true of the second rigid member 98b.

Then the process of producing the magnetic recording medium 10 by using the apparatus 50A of FIG. 2 according to the first embodiment will be described below.

First the substrate 12 coated with the undercoating layer 14 previously is placed on the feed roll 58 and let out.

The transfer rate of feeding the substrate 12 is preferably 1 cm/minute to 10 m/minute, more preferably 10 cm/minute to 8 m/minute. A transfer rate less than 1 cm/minute results in poor productivity. When the transfer rate is more than 10 m/minute, the misalignment of the substrate 12 during transfer can be non-negligibly large.

The unrolled substrate 12 is heated by the heating roll 70 to release gases contained in the substrate 12. The surface temperature of the film forming roll 62 is controlled within the range of (the standard temperature of −20° C. to 40° C.±2° C.), and the substrate 12 is directed through the first opening 96a in the vacuum separator 86, brought into close contact with the film forming roll 62, and then transferred to the first to sixth vacuum sections 64a to 64f by rotating the film forming roll 62.

The polyester-based polymer used for the substrate 12 has a glass transition temperature of approximately 100° C., and the temperature of the substrate 12 can be controlled at 60° C. or less to prevent the heat deformation by controlling the surface temperature of the film forming roll 62 within the above range in this manner. The surface temperature of the film forming roll 62 is more preferably 0 to 20° C.

The flow rate of the refrigerant circulated inside the film forming roll 62 is preferably 3 L/minute or more, more preferably 5 L/minute or more, and is preferably at most 100 L/minute. When the refrigerant flow rate is less than 3 L/minute or more than 100 L/minute, it tends to be difficult to control the surface temperature and the circulation unit is excessively costly to defeat the purpose.

In the second and third vacuum sections 64b and 64c, the first and second underlayers 16 and 18 are formed by the first and second sputtering units 72a and 72b while bringing the substrate into close contact with the film forming roll 62 having the controlled surface temperature. Sputtering methods for forming the first and second underlayers 16 and 18 include known DC sputtering methods and RF sputtering methods. By using the sputtering method for forming the first and second underlayers 16 and 18, the resultant magnetic recording medium 10 can be excellent in magnetic characteristics and high density recording characteristics.

A sputtering gas for the sputtering method of forming the first and second underlayers 16 and 18 may be a common argon gas or another noble gas. Further, a trace of oxygen gas may be used in the sputtering to achieve a crystallinity control or surface oxidation

Then, the substrate 12 is transferred to the fourth vacuum section 64d, and the magnetic layer 20, e.g. a granular magnetic layer, is formed on the second underlayer 18 by a vacuum film forming method using the third sputtering unit 72c.

A sputtering method for forming the magnetic layer 20 may be a known DC sputtering method or RF sputtering method, etc. A high-quality ultrathin film can be easily formed by the method. A sputtering gas for the sputtering method may be a common argon gas or another noble gas. Further, a trace of oxygen gas may be used in the sputtering to control the oxygen content of the magnetic layer 20 or oxidize the surface.

The Ar gas pressure in the sputtering method for forming the magnetic layer 20 is preferably 0.1 to 10 Pa, particularly preferably 0.4 to 7 Pa. When the Ar gas pressure in the film formation is 0.1 Pa or more, the magnetic particles can be separated and the film stress can be relaxed, whereby deformation and film cracking of the substrate 12 is unlikely to be caused. On the other hand, when the Ar gas pressure in the film formation is 10 Pa or less, the crystallinity and film strength can be maintained.

The electric power applied to form the magnetic layer 20 by the sputtering is preferably 0.1 to 100 W/cm², particularly preferably 1 to 50 W/cm². A sputtered particle energy necessary to secure the crystallinity and film adhesion can be provided by applying the electric power of 0.1 W/cm² or more. On the other hand, when the electric power is 100 W/cm² or less, the impact on the substrate 12 is prevented from becoming excessive, and deformation of the substrate and cracking of the films formed are averted.

The magnetic layer 20 thus formed is then subjected to a glow treatment using the argon ion gun 74 in the fifth vacuum section 64e. Then, at least one protective layer 22 is formed on the magnetic layer in the sixth vacuum section 64f while bringing the substrate 12 into close contact with the film forming roll 62, and the resultant substrate 12 is taken up on the take-up roll 60. The protective layer 22 is preferably formed by known plasma CVD, ion beam deposition, filtered cathodic vacuum arc, etc.

In the case of using DLC as a material of the protective layer 22, the film hardness largely depends on the temperature of the substrate 12, and the substrate 12 has to have a low temperature to obtain a protective layer 22 with sufficient film hardness and sliding characteristics. Thus, it is particularly preferred that the protective layer 22 is formed while bringing the substrate 12 into close contact with the film forming roll 62 having the control surface temperature as described above.

After the first underlayer 16, the second underlayer 18, the magnetic layer 20, and the protective layer 22 are formed on the one side of the substrate 12 through 1 process (1 pass) in the above manner, the same layers may be formed on the other side of the substrate 12 through the same 1 process (1 pass). The term “1 process (1 pass)” as used herein denotes the steps of unrolling the substrate 12 from the feed roll 58, forming a desired film, and taking up the substrate 12.

When the layers are formed through the 1 process, it is preferred that the partitions 66 are disposed between the vacuum sections, and the vacuum sections are each equipped with independent evacuation systems, to provide a pressure differential between the adjacent vacuum sections as described above. Furthermore, it is preferred that the pressure differential between the adjacent vacuum sections can provide a cross-contamination (gas mixing) of 30% or less.

The term “cross-contamination (gas mixing)” as used herein means mixing of gases between adjacent vacuum sections. It is preferred that such a cross-contamination be reduced sufficiently, and the reduction of the cross-contamination can be achieved by providing a gas mixing reducing member between the adjacent vacuum sections.

The gas mixing reducing member includes a differential pressure section and the partition 66. By providing such a gas mixing reducing member, layers having the respective desired characteristics can be formed to further improve the characteristics of the resultant magnetic recording medium 10.

In the case of disposing the partition 66 as the gas mixing reducing member between the adjacent vacuum sections, the partition 66 preferably has a T-shaped portion 66a at the end closer to the film forming roll 62 as shown in FIG. 2. The partition 66 with such a shape can more securely reduce the cross-contamination between the adjacent vacuum sections.

For example, between the second and third vacuum sections 64b and 64c, the T-shaped portion 66a formed at the end of the partition 66 can inhibit a gas G1 flowing from the first sputtering unit 72a toward the substrate 12 from entering the third vacuum section 64c.

The cross-contamination may be measured as follows. In the case of measuring the cross-contamination between the second and third vacuum sections 64b and 64c, for example, a sensor is attached to the second sputtering unit 72b, and a gas is introduced only to the first sputtering unit 72a and detected by the sensor. The sensor may be a vacuum gauge.

When the 1 process is completed, the feed roll 58 and the take-up roll 60 are replaced. In the replacement step, the film forming chamber 56 is not opened to atmospheric pressure to maintain the vacuum state.

Thus, as described above, the substrate 12 is unrolled from the feed roll 58, the first underlayer 16, the second underlayer 18, the magnetic layer 20, and the protective layer 22 are formed on the one side of the unrolled substrate 12 in the film forming chamber 56, and thus obtained long magnetic recording material (film) 68 is taken up on the take-up roll 60.

When a so-called margin of the substrate 12 starts to be unrolled from the feed roll 58, the film formation on the substrate 12 in the film forming chamber 56 is stopped once. The rotation transfer of the substrate 12 by the film forming roll 62, etc. is continued, the margin of the substrate 12 passes through the film forming chamber 56 and reaches the take-up roll 60. Then Close-order is input by the input device 92 into the first and second shutters 88a and 88b, so that the shutters 88a and 88b are converted to the closed state, thereby closing the first and second openings 96a and 96b. At this time, the substrate 12 (the margin in this case) is pressed by the first rigid member 98a and the first elastic member 100a in the first opening 96a, and is pressed by the second rigid member 98b and the second elastic member 100b in the second opening 96b.

Then, the roll chamber 54 is opened, and the feed roll 58 and the take-up roll 60 are replaced. Even when the first and second shutters 88a and 88b are closed and the roll chamber 54 is under atmospheric pressure, the vacuum degree of the film forming chamber 56 is maintained at 1×10⁻¹ Pa or less.

Next, for example, a part of the margin in the roll chamber 54 is cut, and the take-up roll 60 is detached from the roll chamber 54 and attached as another feed roll 58. Another take-up roll 60 is attached to the portion in which the detached take-up roll 60 is placed.

A part of the margin is drawn from the another feed roll 58 (the detached take-up roll 60), and the drawn part is connected with an adhesive tape, etc. to another part of the margin pressed by the first rigid member 98a and the first elastic member 100a in the first opening 96a.

Further, a part of the margin pressed by the second rigid member 98b and the second elastic member 100b in the second opening 96b is taken up on the another take-up roll 60. The roll chamber 54 is evacuated by the vacuum pump 80a. Then Open-order is input by the input device 92 into the first and second shutters 88a and 88b, so that the shutters 88a and 88b are converted to the open state, thereby opening the first and second openings 96a and 96b. At this time, the substrate 12 (the margin in this case) is freed from the pressure of the first rigid member 98a and the first elastic member 100a, and the second rigid member 98b and the second elastic member 100b. Preparation for the next film formation is completed in this manner.

Then, the substrate 12 having the magnetic layer 20, etc. on the one side is unrolled from the feed roll 58, the first underlayer 16, the second underlayer 18, the magnetic layer 20, and the protective layer 22 are formed on the other side of the unrolled substrate 12 in the film forming chamber 56, and thus obtained long magnetic recording material 68 is taken up on the take-up roll 60.

Then, when a margin of the substrate 12 starts to be unrolled from the feed roll 58, the film formation on the substrate 12 in the film forming chamber 56 is stopped once. When the margin of the substrate 12 passes through the film forming chamber 56 and reaches the take-up roll 60, Close-order is input again by the input device 92 into the first and second shutters 88a and 88b, so that the shutters 88a and 88b are converted to the closed state, thereby closing the first and second openings 96a and 96b. Then the roll chamber 54 is opened, and the feed roll 58 and the take-up roll 60 are replaced. The obtained magnetic recording material 68 wound on the take-up roll 60 has the magnetic layer 20, etc. on both sides of the substrate, so that the take-up roll 60 is detached and then subjected to the next step such as a lubricant layer forming step. Also the feed roll 58 is detached, and another feed roll 58 with another substrate 12 wound is attached.

This replacement is carried out in the same manner as above. Thus, a part of the margin of the substrate 12 in the roll chamber 54 is cut, the take-up roll 60 is detached from the roll chamber 54 and transferred, and also the feed roll 58 is detached. Then, the another feed roll 58 and another take-up roll 60 are attached respectively.

A part of the margin is drawn from the another feed roll 58, and the drawn part is connected with an adhesive tape, etc. to another part of the margin pressed by the first rigid member 98a and the first elastic member 100a in the first opening 96a.

Further, a part of the margin pressed by the second rigid member 98b and the second elastic member 100b in the second opening 96b is taken up on the another take-up roll 60. Preparation for the next film formation is completed in this manner.

The lubricant layer 24 (see FIG. 1), etc. is formed on the protective layer 22 of the magnetic recording material 68 having the first underlayer 16, the second underlayer 18, the magnetic layer 20, and the protective layer 22 if necessary, and the resultant material is cut into a desired size and put in a cartridge, to produce the magnetic recording medium 10.

The lubricant layer 24 may be formed such that a solution prepared by dissolving a lubricant in an organic solvent is applied to the protective layer 22 by spin coating, wire bar coating, gravure coating, dip coating, etc., or a lubricant is attached to the protective layer 22 by vacuum deposition. The amount of the lubricant is preferably 1 to 30 mg/m², particularly preferably 2 to 20 mg/m².

Even in a case where the feed roll 58 and/or the take-up roll 60 in the roll chamber 54 are replaced several to several tens times by repeating the above steps, the film forming chamber 56 is not opened to atmospheric pressure and its vacuum state is maintained.

Thus, the film forming chamber 56 is not opened to atmospheric pressure to maintain the vacuum state in the replacement of the feed roll 58 and/or the take-up roll 60, so that an attached film (e.g., a sputter film) deposited inside the film forming chamber 56 is protected from contamination with the air in the production of a long film produce. Further, the attached film hardly peels off and is thus prevented from adhering to the film or the magnetic recording material 68, whereby defects of the magnetic recording medium 10 are markedly reduced.

Further, because the first and second openings 96a and 96b are closed and only the roll chamber 54 is evacuated after replacing the feed roll 58 and/or the take-up roll 60, the evacuation time required for the desired vacuum degree can be reduced, thereby resulting in remarkably improved productivity. In the case of forming another magnetic layer 20 in vacuum after the replacement, it is preferred that the roll chamber 54 is evacuated by the vacuum pump 80a to the vacuum degree equal to or less than that of the film forming chamber 56, and the first and second openings 96a and 96b are opened after the evacuation. When the vacuum degree of the roll chamber 54 is equal to or less than that of the film forming chamber 56, the contamination of the film forming chamber 56 can be prevented more securely, whereby the defects of the magnetic recording medium 10 can be further reduced.

Furthermore, the interval of cleaning (maintenance) of the film forming chamber 56 can be lengthened, and the evacuation time of the film forming chamber 56 can be reduced, thereby resulting in remarkably improved productivity. Additionally, since the atmosphere in the film forming chamber 56 can be maintained constant, a layer with desired film qualities can be stably formed on the substrate 12 to improve the qualities of the magnetic recording medium 10.

The apparatus 50B according to the second embodiment will be described below with reference to FIG. 7. Parts identified with the same numerals as in FIG. 2 may be identical and will not be redundantly described.

As shown in FIG. 7, the apparatus 50B according to the second embodiment has a structure similar to that of the apparatus 50A according to the first embodiment, and is different from the apparatus 50A in that the roll chamber is divided into 2 roll chambers (a first roll chamber 54a and a second roll chamber 54b).

The first roll chamber 54a is adjacent to a first vacuum section 64a, and a feed roll 58 can be placed therein. The second roll chamber 54b is adjacent to a sixth vacuum section 64f, and a take-up roll 60 can be placed therein. The first and second roll chambers 54a and 54b contains independent vacuum evacuation systems (vacuum pumps) 80a and 80g respectively.

For example, 1 partition (a first partition-94a) is formed at the boundary portion between the first roll chamber 54a and the first vacuum section 64a, and the first partition 94a has a first opening 96a, which a substrate 12 unrolled from the feed roll 58 passes through. A first rigid member 98a is disposed on the right inner wall of the first opening 96a, and a first elastic member 100a is disposed on the left inner wall. In the first partition 94a, a first reciprocating unit 102a (see FIG. 4) for reciprocating the first elastic member 100a toward the first rigid member 98a or a first pump unit 106a (see FIG. 5) is disposed between the first elastic member 100a and the inner wall of the vacuum chamber 52, and a fluid can be charged into and discharged (evacuated) from a hollow portion 104a of the first elastic member 100a by the first pump unit 106a.

In the same manner, 1 partition (a second partition 94b) is formed at the boundary portion between the second roll chamber 54b and the sixth vacuum section 64f, and the second partition 94b has a second opening 96b, which the substrate 12 to be taken up on the take-up roll 60 passes through. A second rigid member 98b is disposed on the left inner wall of the second opening 96b, and a second elastic member 100b is disposed on the right inner wall. In the second partition 94b, a second reciprocating unit 102b (see FIG. 4) for reciprocating the second elastic member 100b toward the second rigid member 98b or a second pump unit 106b (see FIG. 5) is disposed between the second elastic member 100b and the inner wall of the vacuum chamber 52, and a fluid can be charged into and discharged (evacuated) from a hollow portion 104a of the second elastic member 100b by the second pump unit 106b.

To produce the magnetic recording medium 10 by the apparatus 50B according to the second embodiment, the roll of the substrate 12 with an undercoating layer 14, etc. is unrolled from the feed roll 58, a first underlayer 16, a second underlayer 18, a magnetic layer 20, and a protective layer 22 are formed in this order on a film forming roll 62, and the resultant substrate 12 is taken up on the take-up roll 60 in the same manner as above.

The apparatus 50B has the same advantages as the apparatus 50A according to the first embodiment, and also in production of the magnetic recording medium 10 by using the apparatus 50B, the feed roll 58 and the take-up roll 60 can be replaced such that first and second shutters 88a and 88b are converted to the closed state to close the first and second openings 96a and 96b, and then only the first and second roll chambers 54a and 54b are opened.

Particularly, in the apparatus 50B according to the second embodiment, the feed roll 58 is contained in the first roll chamber 54a and the take-up roll 60 is contained in the second roll chamber 54b, whereby the sizes of the first and second roll chambers 54a and 54b can be reduced to achieve space saving, and the time of the opening to atmospheric pressure and evacuation can be remarkably reduced to improve the productivity.

The apparatus 50C according to the third embodiment will be described with reference to FIG. 8.

The apparatus 50C according to the third embodiment has a structure similar to that of the apparatus 50B according to the second embodiment, and is different from the apparatus 50B in that a first underlayer 16, a second underlayer 18, a magnetic layer 20, and a protective layer 22 are formed on each of the both surfaces of a substrate 12 in 1 process (1 pass).

Thus, in the apparatus 50C, a first film forming roll 62a and a second film forming roll 62b are disposed in a film forming chamber 56 rotatably, and for example, 6 vacuum sections (first to sixth vacuum sections 64a to 64f) are placed around the first film forming roll 62a and 6 vacuum sections (eleventh to sixteenth vacuum sections 108a to 108f) are placed around the second film forming roll 62b.

The first vacuum section 64a has a heating roll 70 for heating the substrate 12 from a feed roll 58, the second vacuum section 64b has a first sputtering unit 72a for forming the first underlayer 16 on one side of the substrate 12, the third vacuum section 64c has a second sputtering unit 72b for forming the second underlayer 18 on the one side of the substrate 12, the fourth vacuum section 64d has a third sputtering unit 72c for forming the magnetic layer 20 on the one side of the substrate 12, the fifth vacuum section 64e has a first argon ion gun 74a for glow-treating the one side of the substrate 12, and the sixth vacuum section 64f has a first protective layer forming unit 76a for forming the protective layer 22 on the one side of the substrate 12.

Further, the eleventh vacuum section 108a has a fourth sputtering unit 72d for forming a first underlayer 16 on the other side of the substrate 12, the twelfth vacuum section 108b has a fifth sputtering unit 72e for forming the second underlayer 18 on the other side of the substrate 12, the thirteenth vacuum section 108c has a sixth sputtering unit 72f for forming the magnetic layer 20 on the other side of the substrate 12, the fourteenth vacuum section 108d has a second argon ion gun 74b for glow-treating the other side of the substrate 12, the fifteenth vacuum section 108e has a second protective layer forming unit 76b for forming the protective layer 22 on the other side of the substrate 12, and the sixteenth vacuum section 108f has a transfer roll, etc. for conveying the substrate 12 toward the take-up roll 60.

Further, a first roll chamber 54a containing the feed roll 58 is placed in the vicinity of the first vacuum section 64a, and a second roll chamber 54b containing the take-up roll 60 is placed in the vicinity of the sixteenth vacuum section 108f.

The second to sixth vacuum sections 64b to 64f have independent vacuum pumps 80b to 80f respectively, also the eleventh to fifteenth vacuum sections 108a to 108e have independent vacuum pumps 110a to 110e respectively, and also the first and second roll chambers 54a and 54b have independent vacuum pumps 80a and 80g respectively.

Further, a first partition 94a is formed at a boundary portion between the first roll chamber 54a and the first vacuum section 64a, and the first partition 94a has a first opening 96a which the substrate 12 unrolled from the feed roll 58 passes through For example, a first rigid member 98a is disposed on the left inner wall of the first opening 96a, and a first elastic member 100a is disposed on the right inner wall. In the first partition 94a, a first reciprocating unit 102a (see FIG. 4) for reciprocating the first elastic member 100a toward the first rigid member 98a or a first pump unit 106a (see FIG. 5) is disposed between the first elastic member 100a and the inner wall of the vacuum chamber 52, and a fluid can be charged into and discharged (evacuated) from a hollow portion 104a of the first elastic member 100a by the first pump unit 106a.

In the same manner a second partition 94b is placed at a boundary portion between the second roll chamber 54b and the sixteenth vacuum section 108f, and the second partition 94b has a second opening 96b which the substrate 12 to be taken up on the take-up roll 60 passes through. For example, a second rigid member 98b is disposed on the left inner wall of the second opening 96b, and a second elastic member 100b is disposed on the right inner wall. In the second partition 94b, a second reciprocating unit 102b (see FIG. 4) for reciprocating the second elastic member 100b toward the second rigid member 98b or a second pump unit 106b (see FIG. 5) is disposed between the second elastic member 100b and the inner wall of the vacuum chamber 52, and a fluid can be charged into and discharged (evacuated) from a hollow portion 104b of the second elastic member 100b by the second pump unit 106b.

To produce the magnetic recording medium 10 by the apparatus 50C according to the third embodiment, the roll of the substrate 12 with an undercoating layer 14, etc. is unrolled from the feed roll 58, the first underlayer 16, second underlayer 18, magnetic layer 20, and protective layer 22 are formed in this order on the one side of the substrate 12 on the first film forming roll 62a, the other first underlayer 16, second underlayer 18, magnetic layer 20, and protective layer 22 are formed in this order on the other side of the substrate 12 on the second film forming roll 62b, and the resultant substrate 12 is taken up on the take-up roll 60.

The apparatus 50C has the same advantages as the apparatus 50A according to the first embodiment, and also in production of the magnetic recording medium 10 by using the apparatus 50C, the feed roll 58 and the take-up roll 60 can be replaced such that first and second shutters 88a and 88b are converted to the closed state to close the first and second openings 96a and 96b, and then only the first and second roll chambers 54a and 54b are opened.

Further, the feed roll 58 is contained in the first roll chamber 54a and the take-up roll 60 is contained in the second roll chamber 54b in the apparatus 50C according to the third embodiment as the apparatus 50B according to the second embodiment, whereby the sizes of the first and second roll chambers 54a and 54b can be reduced to achieve space saving, and the time of the opening to atmospheric pressure and evacuation can be remarkably reduced to improve the productivity.

Particularly in the third embodiment, the first underlayer 16, second underlayer 18, magnetic layer 20, and protective layer 22 can be formed on each of the both surfaces of the substrate 12 in the 1 process (1 pass), whereby the numbers of replacing the feed roll 58 and the take-up roll 60 and evacuating the first and second roll chambers 54a and 54b can be greatly reduced to improve the production efficiency.

Next, the substrate 12 and the layers used in the magnetic recording medium 10 according to the embodiments will be described below.

The substrate 12 comprises a flexible resin film to resist shock due to contact of a magnetic head with the magnetic disk or the magnetic tape. The resin film may comprise an aromatic polyimide, aromatic polyamide, aromatic polyamideimide, polyether ketone, polyether sulfone, polyether imide, polysulfone, polyphenylene sulfide, polyethylene naphthalate, polyethylene terephthalate, polycarbonate, cellulose triacetate, fluororesin, etc.

A laminate film of a plurality of resin films may be used as the substrate 12. By using the laminate film, warpage or waving of the substrate 12 per se can be reduced to improve the scratch resistance of the magnetic recording medium 10.

The laminate film may be obtained by lamination techniques such as hot roll lamination, flat hot press lamination, dry lamination of applying an adhesive, lamination of using a previously formed adhesive sheet, etc. The adhesive is not particularly limited, and may be an ordinary hot melt adhesive, thermosetting adhesive, UV curing adhesive, EB curing adhesive, adhesive sheet, anaerobic adhesive, etc.

In the case of using the substrate 12 for flexible disks, the thickness of the substrate 12 is 10 to 200 μm, preferably 20 to 150 μm, more preferably 30 to 100 μm. When the substrate 12 has a thickness of less than 10 μm, the high-speed rotational stability is reduced to increase side-runout. On the other hand, when the substrate 12 has a thickness of more than 200 μm, the substrate 12 is highly rigid and thereby cannot resist the shock due to the contact, to cause jump-up of the magnetic head. In the case of using the substrate 12 for magnetic tapes, the thickness of the substrate 12 is 1 to 20 μm, preferably 3 to 12 μM. When the substrate 12 has a thickness of less than 3 μm, the substrate 12 is insufficient in strength and is likely to undergo cutting or edge bending. On the other hand, when the thickness is more than 20 μm, the magnetic tape length per pack decreases, resulting in reduced recording density per unit volume. Further, the substrate 12 having a thickness of more than 20 μm is highly rigid, thereby resulting in a poor contact with a magnetic head, i.e., poor conformity to a magnetic head.

The stiffness of the substrate 12 is represented by the following equation (1): Stiffness of substrate=Ebd³/12. In the case of the flexible disk, the stiffness of the substrate 12 is preferably 0.5 to 2.0 kgf/mm² (4.9 to 19.6 MPa), more preferably 0.7 to 1.5 kgf/mm² (6.86 to 14.7 MPa), when b is 10 mm.

In the equation (1), E represents a Young's modulus, b represents a film width, and d represents a film thickness.

It is preferred that the surface of the substrate 12 be as smooth as possible in view of recording with a magnetic head. The surface roughness of the substrate 12 significantly influences the signal recording and reproducing characteristics. Specifically, in the case of using the undercoating layer 14 to be hereinafter described, the average centerline roughness Ra of the substrate 12 measured by an optical profilometer is 5 nm or less, preferably 2 nm or less, and the projection height of the substrate 12 measured by a stylus profilometer is 1 μm or less, preferably 0.1 μm or less. In the case of not using the undercoating layer 14, the average centerline roughness Ra of the substrate 12 measured by an optical profilometer is 3 nm or less, preferably 1 nm or less, and the projection height of the substrate 12 measured by a stylus profilometer is 0.1 μm or less, preferably 0.06 μm or less.

The undercoating layer 14 is formed to improve surface smoothness of the substrate 12 and to provide gas barrier properties. Since the magnetic layer 20 is formed by a vacuum film forming method such as sputtering in this embodiment, it is preferred that the undercoating layer 14 be excellent in heat resistance. Examples of materials usable for the undercoating layer 14 include polyimide resins, polyamideimide resins, silicone resins, and fluororesins. Thermosetting polyimide resins and thermosetting silicone resins are particularly preferred for their high smoothing effect. The undercoating layer 14 preferably has a thickness of 0.1 to 3.0 μm. In the case of forming a laminate of the other resin film on the substrate 12, the undercoating layer 14 may be formed before or after the lamination.

Preferred thermosetting polyimide resins include those obtained by thermal polymerization of an imide monomer containing at least two unsaturated end groups per molecule, such as a bisallylnadiimide BANI available from Maruzen Petrochemical Co., Ltd. The imide monomer is allowed to be applied to the substrate 12 and then thermally polymerized and hardened at a relatively low temperature on the substrate 12. The imide monomer is soluble in universal solvents to have excellent productivity and workability. Further, the imide monomer has a low molecular weight and provides a low viscosity solution, and thus can easily fill up surface depressions to show high smoothing effect.

Preferred thermosetting silicone resins include those prepared by a sol-gel method using a silicon compound with an organic group as a starting material. The silicone resins prepared in this manner have a structure of silicon dioxide with part of its bonds substituted with the organic group, and is much more heat-resistant than silicone rubbers and more flexible than silicon dioxide. Thus, the resin film of the silicone resins, which is formed on the flexible polymer substrate 12, is unlikely to be cracked or peeled off. Since the monomer for the silicone resins is allowed to be applied directly to the substrate 12 followed by setting, universal solvents are employable to prepare a monomer solution, which easily fills up surface depressions to show high smoothing effect. Polycondensation of the monomer can be carried out at a relatively low temperature by adding a catalyst such as an acid or a chelating agent, whereby the hardening reaction can be completed in a short time and the resin film can be formed by using a universal coating apparatus. Furthermore, the thermosetting silicone resins are particularly preferred because they have excellent gas barrier properties to be capable of blocking a gas generated from the substrate 12 during the formation of the magnetic layer 20, which deteriorates the crystallinity and orientation of the magnetic layer 20 or the underlayers (the first and second underlayers 16 and 18).

For the purpose of reducing the true contact area between the magnetic head and magnetic disk to improve the sliding characteristics, it is preferred to provide the surface of the magnetic recording medium 10 with microprojections (or a texture) 28 as shown in FIG. 1. The handling properties of the substrate 12 is improved by forming the microprojections 28. The microprojections 28 may be formed by a method of applying spherical silica particles 30 to the undercoating layer 14 or a method of applying an emulsion to form projections of an organic substance, etc. In view of securing the high heat resistance of the undercoating layer 14, the microprojections 28 are preferably formed by applying the spherical silica particles 30.

The height h of each microprojection 28 is preferably 5 to 60 nm, more preferably 10 to 30 nm. Too high microprojections 28 result in increased spacing loss between the recording reproducing head and the magnetic recording medium 10, which deteriorates the signal recording and reproducing characteristics. Too low microprojections 28 result in a poor effect of improving the sliding characteristics. The number of the microprojections 28 per 1 μm² area is preferably 0.1 to 100, more preferably 1 to 10. When the number of the microprojections 28 is too small, the microprojections 28 are poor in the effect of improving the sliding characteristics. When the number of the microprojections 28 is too large, the particles are excessively aggregated to increase the height of the microprojections 28, resulting in poor recording and reproducing characteristics.

The microprojections 28 can be fixed to the substrate 12 by a binder. The binder is preferably a resin having a sufficient heat resistance, particularly preferably a solvent-soluble polyimide resin, a thermosetting polyimide resin, or a thermosetting silicone resin.

The first and second underlayers 16 and 18 are formed to control the adhesion, the gas barrier properties, and the crystal orientation of the magnetic layer 20. Examples of materials for the first and second underlayers 16 and 18 include Si, Ti Ni, B, NiP, and oxides and nitrides thereof, carbon, NiAl alloys, Ru, RuAl alloys, Re, Cr, and Cr alloys. The thicknesses of the first and second underlayers 16 and 18 are preferably 5 to 50 nm, more preferably 10 to 40 nm. It should be noted that the number of underlayers is not limited to two.

The magnetic layer 20 may be a CoPtCr-based magnetic layer commonly used in hard disks, a magnetic layer having a granular structure that can be formed at room temperature, a magnetic layer having an artificial lattice structure, etc. By using such a metal thin film magnetic layer, the resultant magnetic recording medium can show a high coercive force and a low noise.

Specific examples of the magnetic layers include films of CoPtCr, CoPtCrB, CoCr, CoPtCrTa, CoPt, CoPtCr—SiO₂, CoPtCr—TiO₂, CoPtCr—Cr₂O₃, CoPtCrB—SiO₂, CoRuCr, and CoRuCr—SiO₂, multilayer films of Co/Pt and Co/Pd.

The thickness of the magnetic layer 20 is preferably 5 to 60 nm, more preferably 5 to 30 nm. When the thickness is larger, the magnetic particles are excessively grown to increase interaction between the particles to markedly increase the noise, and the resultant layer is poor in the resistance to stress due to the contact of the head and the medium, to reduce the running durability. When the thickness is smaller, the output is remarkably reduced.

The magnetic layer 20 may be a longitudinal (in-plane) magnetic recording layer whose easy magnetization axis is parallel to the substrate 12 or a perpendicular magnetic recording layer whose easy magnetization axis is in the direction perpendicular to the substrate 12. The direction of the easy magnetization axis can be controlled by changing the materials and crystal structures of the first and second underlayers 16 and 18, and the composition and the film forming conditions of the magnetic layer,

The protective layer 22 is formed to prevent corrosion of the metallic material in the magnetic layer 20 and wear of the magnetic disk due to pseudo-contact or sliding contact with a magnetic head, thereby improving the running durability and corrosion resistance.

Examples of materials usable in the protective layer 22 include oxides such as silica, alumina, titania, zirconia, cobalt oxide, and nickel oxide; nitrides such as titanium nitride, silicon nitride, and boron nitride; carbides such as silicon carbide, chromium carbide, and boron carbide; and carbons such as graphite and amorphous carbon.

It is preferred that the protective layer 22 is a rigid film having a hardness equal to or higher than that of the magnetic head such that it can prevent seizure during sliding in a long time and can show excellent sliding durability. It is more preferred that the protective layer 22 has only a few pinholes and is excellent also in the corrosion resistance. Such protective layers 22 include films of diamond-like carbon DLC.

The protective layer 22 may have a multilayer structure comprising a stack of two or more thin films having different properties. For example, both of the corrosion resistance and the durability can be maintained at high levels by forming a nitrogen-doped, diamond-like carbon protective film for improving the sliding characteristics and corrosion resistance on the outer side and by forming a diamond-like carbon protective film for improving the film hardness on the inner side.

The lubricant layer 24 is formed to improve the running durability and corrosion resistance. The lubricant layer 24 may comprise a lubricant such as a known hydrocarbon lubricant, fluorine lubricant, or extreme pressure additive.

The hydrocarbon lubricants include carboxylic acids such as stearic acid and oleic acid; esters such as butyl stearate; sulfonic acids such as octadecylsulfonic acid; phosphoric esters such as monooctadecyl phosphate; alcohols such as stearyl alcohol and oleyl alcohol; carboxylic amides such as stearamide; and amines such as stearylamine.

The fluorine lubricant may be such that part or the whole of alkyl groups of the hydrocarbon lubricant is displaced with a fluoroalkyl group or a perfluoropolyether group. Examples of the perfluoropolyether groups include those derived from perfluoromethylene oxide polymers, perfluoroethylene oxide polymers, perfluoro-n-propylene oxide polymers (CF₂CF₂CF₂O)ₙ, perfluoroisopropylene oxide polymers (CF(CF₃)CF₂O)ₙ, and copolymers of these monomer units. Specific examples thereof include perfluoromethylene-perfluoroethylene copolymers having a hydroxyl group at the end, such as FOMBLIN Z-DOL available from Ausimont.

These lubricants may be used singly or in combination.

Examples of the extreme pressure additives include phosphoric esters such as trilauryl phosphate; phosphorous esters such as trilauryl phosphite; thiophosphorous esters such as trilauryl trithiophosphite; thiophosphoric esters; and sulfur-based extreme pressure agents such as dibenzyl disulfide.

The lubricants may be used singly or in combination A corrosion inhibitor is preferably used to further increase the corrosion resistance. The corrosion inhibitors include nitrogen-containing heterocyclic compounds such as benzotriazole, benzidazole, purine, and pyrimidine, and derivatives thereof having an alkyl side chain, etc. introduced to their nucleus; and nitrogen- and sulfur-containing heterocyclic compounds, such as benzothiazole, 2-mercaptobenzothiazole, tetraazaindene compounds, and thiouracil compounds, and derivatives thereof. The corrosion inhibitor may be mixed with the lubricant and then applied to the protective layer 22, and may be applied to the protective layer 22 before the application of the lubricant. The amount of the corrosion inhibitor to be applied is preferably 0.1 to 10 mg/m², particularly preferably 0.5 to 5 mg/m².

The lubricant or corrosion inhibitor that can be used in the lubricant layer 24 may be added to the backcoating layer of the magnetic tape. By the addition, the lubricant or corrosion inhibitor can be supplied to the surface in the vicinity of the magnetic layer 20, so that the corrosion resistance of the magnetic layer 20 can be maintained in a long time. Further, the corrosion resistance of the magnetic layer 20 can be increased also by controlling the pH of the backcoating layer. The backcoating layer can be formed by the steps of dispersing a nonmagnetic powder of carbon black, calcium carbonate, alumina, etc., a resin binder such as polyvinyl chloride or polyurethane, and a lubricant or a hardening agent in an organic solvent to prepare a liquid, applying the liquid by gravure coating, wire bar coating, etc., and drying the applied liquid. The corrosion inhibitor or the lubricant may be dissolved in the liquid and may be applied to the formed backcoating layer.

### EXAMPLES

A first experiment example of evaluating magnetic characteristics, defects, and running durability of Examples 1 to 8 and Comparative Examples 1 to 5 will be described below.

Details of Examples 1 to 8 and Comparative Examples 1 to 5 are descriebd below.

### Example 1

An undercoating liquid containing 3-glycidoxypropyltrimethoxysilane, phenyltriethoxysilane, hydrochloric acid, aluminum acetylacetonate, and ethanol was applied to a polyethylene naphtbalate film having a thickness of 63 μm, a surface roughness Ra of 1.4 nm, and a length of 300 m by gravure coating, and dried and hardened at 100° C., to form a 1.0-μm-thick undercoating layer 14 of a silicone resin. A coating liquid containing a silica sol having a particle size of 25 nm and the undercoating liquid was applied to the undercoating layer 14 by gravure coating, to form projections having a height of 15 nm on the undercoating layer 14 at a density of 10 projections/μm². The undercoating layer 14 was formed on both sides of the substrate 12.

The resultant substrate 12 was attached to a feed roll 58 of an apparatus 50A shown in FIG. 2 according to the first embodiment, and was conveyed while bringing the substrate 12 into close contact with a water-cooled film forming roll 62 having a surface property Rz of 0.05 μm. In a second vacuum section 64b, a first underlayer 16 of carbon was formed on the undercoating layer 14 on one side of the substrate 12 by DC magnetron sputtering using a first sputtering unit 72a. The first underlayer 16 was formed under an Ar gas pressure of 0.1 Pa, and had a thickness of 20 nm. Degassing using a heating roll 70 was not conducted.

In a third vacuum section 64c, a 20-nm-thick second underlayer 18 of Ru was formed by using a second sputtering unit 72b under an Ar pressure of 4 Pa. Then, in a fourth vacuum section 64d, a 20-nm-thick magnetic layer 20 of (Co₇₀—Pt₂₀—Cr₁₀)₈₈—(SiO₂)₁₂ was formed using a third sputtering unit 72c under an Ar pressure of 3 Pa. Further, a mixed gas of ethylene gas, nitrogen gas, and argon gas having a mole ratio C:H:N of 62:29:7 was introduced to a sixth vacuum section 64f and a 5-nm-thick, nitrogen-doped DLC protective layer 22 was formed by ion beam deposition under a gas pressure of 0.06 Pa in the sixth vacuum section 64f, and the resultant was taken up on a take-up roll 60. A glow treatment was not carried out in a fifth vacuum section 64e.

Then, first and second shutters 88a and 88b in a vacuum separator 86 placed between a roll chamber 54 and a film forming chamber 56 are converted to the closed state to close both of first and second openings 96a and 96b, so that only the roll chamber 54 was opened to the air. The substrate 12 taken up on the take-up roll 60 was attached to the feed roll 58 such that another magnetic layer 20, protective layer 22, etc. are formed on the other side of the substrate 12. The roll chamber 54 was evacuated again, the first and second shutters 88a and 88b in the vacuum separator 86 were converted to the open state to open the first and second openings 96a and 96b, a first underlayer 16, a second underlayer 18, a magnetic layer 20, and a protective layer 22 were formed on the other side of the substrate 12 in the same manner as above to prepare a magnetic recording material 68 (a film), and the resulting substrate 12 was taken up on the take-up roll 60.

A solution prepared by dissolving a perfluoropolyether lubricant having a hydroxyl group at the molecular end (FOMBLIN Z-DOL available from Ausimont) in a fluorine lubricant (HFE-7200 available from Sumitomo 3M) was applied to the protective layer 22 by gravure coating to form a 1-nm-thick lubricant layer 24. The lubricant layer 24 was formed on each side of the magnetic recording material 68. The resulting material was punched into a 3.5 inch disk, and the disk was burnished with tape and put into a resin cartridge (for Zip 100 available from Fuji Photo Film Co., Ltd.), to produce a flexible disk 10 having the layer structure shown in FIG. 1. The production of the flexible disk 10 was repeated three times to obtain 3 samples.

First and second rigid members 98a and 98b contained in the first and second shutters 88a and 88b in the vacuum separator 86 comprised a material of a stainless steel having a Young's modulus of 7×10¹⁰ Pa or more and a maximum surface roughness (Rz) of 0.4 μm respectively. First and second elastic members 100a and 100b had hollow portion 104a and 104b and comprised a material of viton rubber having a standard hardness of 70° respectively.

When the vacuum separator 86 was closed, the first and second elastic members 100a and 100b was expanded to apply a pressure of 0.3 MPa to the first and second rigid members 98a and 98b respectively, whereby the substrate 12 was sandwiched between the first rigid member 98a and the first elastic member 100a and between the second rigid member 98b and the second elastic member 100b, to maintain the vacuum state of the film forming chamber 56.

### Example 2

Flexible disks 10 were produced in the same manner as Example 1 except for using an apparatus 50B shown in FIG. 7 according to the second embodiment. Materials and characteristics of the members contained in the first and second shutters 88a and 88b in the vacuum separator 86 were equal to those of Example 1.

### Example 3

Flexible disks 10 were produced in the same manner as Example 1 except that the first underlayer 16, second underlayer 18, magnetic layer 20, and protective layer 22 were formed on each of the both sides of the substrate 12 in 1 process (1 pass) by using an apparatus 50C shown in FIG. 8 according to the third embodiment. Materials and characteristics of the members contained in the first and second shutters 88a and 88b in the vacuum separator 86 were equal to those of Example 1.

### Example 4

A polyamide film having a thickness of 9 μm and a surface roughness Ra of 1.0 nm was used as the substrate 12, the first underlayer 16, second underlayer 18, magnetic layer 20, protective layer 22, and lubricant layer 24 were formed on one side of the substrate 12 in the same manner as Example 1, and a backcoating layer of carbon black was formed on the other side of the substrate 12 and slit without forming the first underlayer 16, second underlayer 18, magnetic layer 20, and protective layer 22, to produce a magnetic tape 10 having a width of 8 mm.

### Example 5

Flexible disks 10 were produced in the same manner as Example 1 except for using a plasma CVD method for forming a DLC protective layer.

### Example 6

Flexible disks 10 were produced in the same manner as Example 1 except that the substrate 12 was subjected to an Ar glow treatment in the fifth vacuum section 64e after the formation of the magnetic layer 20, and then the DLC protective layer 22 was formed thereon in the sixth vacuum section 64f

### Example 7

Flexible disks 10 were produced in the same manner as Example 1 except that the surface temperature of the heating roll 70 was controlled at 70° C. in the first vacuum section 64a and degassing was carried out.

### Example 8

Flexible disks 10 were produced in the same manner as Example 1 except the following points.

The film forming roll 62 was heated at 200° C., and a 20-nm-thick first underlayer 16 of Ta was formed under an Ar pressure of 1.0 Pa in the second vacuum section 64b. Then, a 60-nm-thick second underlayer 18 of Cr₈₀—Ti₂₀ was formed under an Ar pressure of 2 Pa in the third vacuum section 64c, a 20-nm-thick magnetic layer 20 of Co₇₀—Pt₁₀—Cr₂₀ was formed under an Ar pressure of 1.5 Pa in the fourth vacuum section 64d, and the resulting material was taken up on the take-up roll 60.

In the second pass, the film forming roll 62 was cooled to 15° C., a mixed gas of ethylene gas, nitrogen gas, and argon gas having a mole ratio C:H:N of 62:29:7 was introduced to the sixth vacuum section 64f, and a 5-nm-thick, nitrogen-doped DLC protective layer 22 was formed by ion beam deposition under a gas pressure of 0.06 Pa in the sixth vacuum section 64f, and the resultant was taken up on a take-up roll 60.

### Comparative Example 1

Flexible disks were produced in the same manner as Example 1 except that an apparatus having no vacuum separators 86 to be unable to separate vacuum of the roll chamber 54 and the film forming chamber 56 was used, and the first underlayer 16, second underlayer 18, magnetic layer 20, and protective layer 22 were formed on the one side, the entire vacuum chamber 52 was opened to the air, thus obtained material was attached to the feed roll 58, the entire vacuum chamber 52 was evacuated, and the first underlayer 16, second underlayer 18, magnetic layer 20, and protective layer 22 were formed on the other side of the substrate 12.

### Comparative Example 2

Flexible disks were produced in the same manner as Comparative Example 1 except that a web sputtering unit using a common vacuum evacuation system in the vacuum sections was used, the first underlayer 16, second underlayer 18, and magnetic layer 20, and a 5-nm-thick sputtered carbon protective layer were formed on the one side of the substrate 12 in 4 passes, and the layers were formed on the other side in another 4 passes. The protective layer was formed under an Ar pressure of 0.06 Pa

### Comparative Example 3

Flexible disks were produced in the same manner as Example 3 except that an apparatus having no vacuum separators 86 to be unable to separate vacuum of the roll chamber 54 and the film forming chamber 56 was used, and the first underlayer 16, second underlayer 18, magnetic layer 20, and protective layer 22 were formed on each of the both sides. The take-up roll 60 was replaced after opening the entire vacuum chamber 52 to the air, and the entire vacuum chamber 52 was evacuated again before the next production of the sample.

### Comparative Example 4

Flexible disks were produced in the same manner as Comparative Example 3 except that an apparatus using a common vacuum evacuation system in the vacuum sections was used, and the first underlayer 16, second underlayer 18, and magnetic layer 20, and a 5-nm-thick sputtered carbon protective layer were formed in 4 passes on each side of the substrate 12. The protective layer was formed under an Ar pressure of 0.06 Pa.

### Comparative Example 5

Magnetic tapes were produced in the same manner as Example 4 except that an apparatus having no vacuum separators 86 to be unable to separate vacuum of the roll chamber 54 and the film forming chamber 56 was used. Before the next production of the sample, the entire vacuum chamber 52 was opened to the air and then evacuated again.

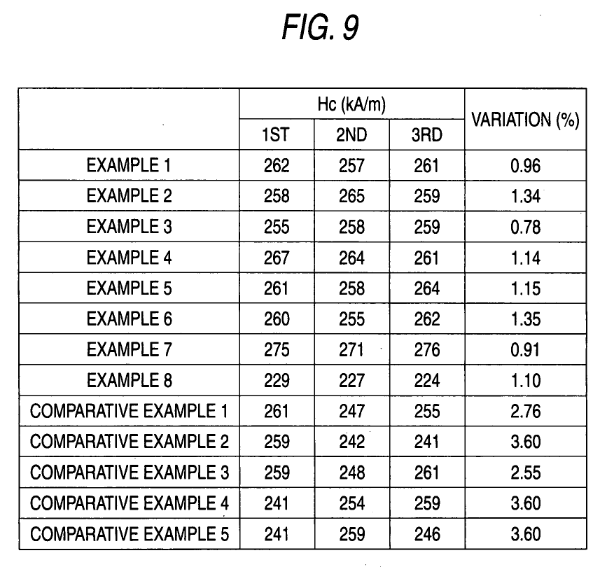

Then, the coercive forces Hc of the samples measured by VSM to evaluate the magnetic characteristics of the samples. In the case of the flexible disks, measurement was taken on both sides to obtain an average. The measurement was made once for each of three samples, and the variation was calculated from the following equation: Variation=(maximum−minimum)/(maximum+minimum)×100 [%]. The results of evaluating the magnetic characteristics are shown in FIG. 9.

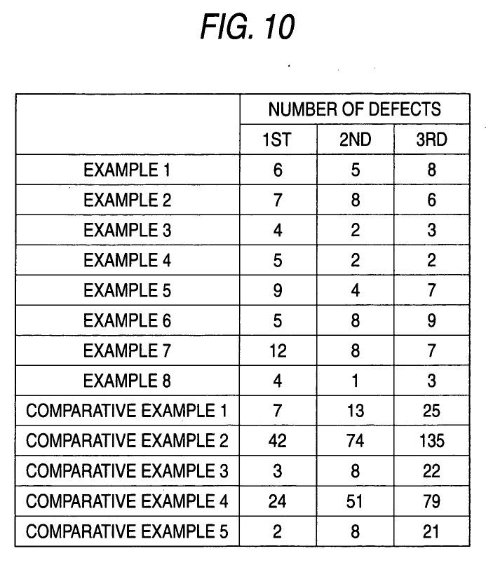

The number of defects of 1 μm or larger per 3.5-inch surface of each flexible disk was counted by a surface analyzer. And the number of defects of 1 μm or larger per 8 mm×1 m surface of each magnetic tape was counted by the surface analyzer. The results are shown in FIG. 10.

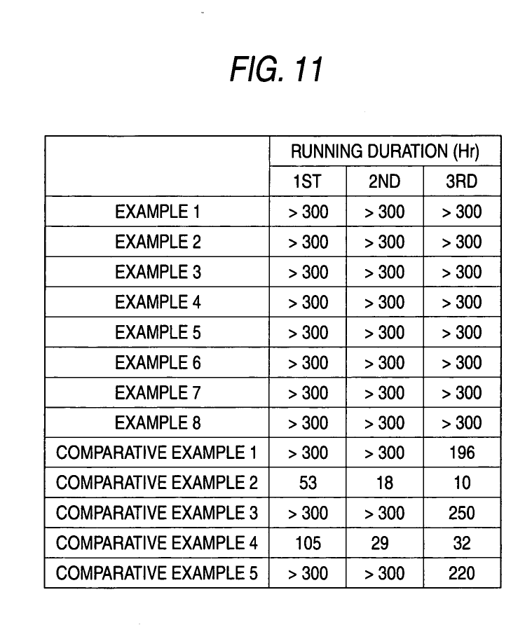

Signals were recorded on each medium at a linear recording density of 400 kFCI and repeatedly reproduced with a GMR head having a reading track width of 0.25 μm and a read gap of 0.09 μm. At the time when the output dropped by 3 dB from the initial one, the running was stopped, and the running time was taken as a duration. The testing atmosphere was 23° C. and 50% RH, and the running test was terminated at 300 hours. The results of evaluating running durability are shown in FIG. 11.

As is clear from the results shown in FIGS. 9 to 11, the flexible disks 10 and magnetic tapes 10 produced according to the present invention exhibited stable magnetic characteristics and a stably reduced level of surface defects, and thereby had stable, high running durabilities and high productivities.

In contrast, the samples of Comparative Examples 1 to 5, in which the entire vacuum chamber 52 was opened to the air, achieved magnetic characteristics but lack in stability thereof. They underwent increased defects with passes. The results of the running durability test also revealed that the products were not reliable.

An experiment example of evaluating magnetic characteristics, deformation of substrate, and running durability of Examples 11 to 14 and Comparative Examples 11 to 13 will be described below.

Details of Examples 11 to 14 and Comparative Examples 11 to 13 are descriebd below.

### Example 11

An undercoating liquid containing 3-glycidoxypropyltrimethoxysilane, phenyltriethoxysilane, hydrochloric acid, aluminum acetylacetonate, and ethanol was applied to a polyethylene naphthalate film having a thickness of 63 μm, a surface roughness Ra of 1.4 nm, and a length of 300 m by gravure coating, and dried and hardened at 100° C., to form a 1.0-μm-thick undercoating layer 14 of a silicone resin. A coating liquid containing a silica sol having a particle size of 25 nm and the undercoating liquid was applied to the undercoating layer by gravure coating, to form projections having a height of 15 nm on the undercoating layer 14 at a density of 10 projections/m. The undercoating layer 14 was formed on both sides of the substrate 12.

The resultant substrate 12 was attached to a feed roll 58 of an apparatus 50A shown in FIG. 2 according to the first embodiment, and was conveyed while bringing the substrate 12 into close contact with a film forming roll 62 of a stainless steel having a surface property Rz of 0.05 μm and a controlled surface temperature of 15° C. In a second vacuum section 64b, a 20-nm-thick first underlayer 16 of carbon was formed on the undercoating layer 14 under an Ar gas pressure of 0.1 Pa by DC magnetron sputtering using a first sputtering unit 72a. Then, in a third vacuum section 64c, a 20-nm-thick second underlayer 18 of Ru was formed by using a second sputtering unit 72b under an Ar pressure of 4 Pa.

Further, in a fourth vacuum section 64d, a 20-nm-thick granular magnetic layer 20 of (Co₇₀—Pt₂₀—Cr₁₀)₈₈—(SiO₂)₁₂ was formed using a third sputtering unit 72c under an Ar pressure of 3 Pa. Further, a mixed gas of ethylene gas, nitrogen gas, and argon gas having a mole ratio C:H:N of 62:29:7 was introduced to a sixth vacuum section 64f, and a 5-nm-thick, nitrogen-doped DLC protective layer 22 was formed by ion beam deposition using a protective layer forming gun 76 under a gas pressure of 0.06 Pa in the sixth vacuum section 64f, and the resultant was taken up on a take-up roll 60.

Then, the wound substrate 12 was reversed and attached to the feed roll 58, the first underlayer 16, second underlayer 18, magnetic layer 20, and protective layer 22 were formed on the other side of the substrate 12 in the same manner as above, and thus obtained magnetic recording material 68 was taken up on the take-up roll 60.

A solution prepared by dissolving a perfluoropolyether lubricant having a hydroxyl group at the molecular end (FOMBLIN Z-DOL available from Ausimont) in a fluorine lubricant (HFE-7200 available from Sumitomo 3M) was applied to the protective layer 22 by gravure coating to form a 1-nm-thick lubricant layer 24. The lubricant layer 24 was formed on the both sides of the magnetic recording material 68 (film). The resulting material was punched into a 3.5 inch disk, and the disk was burnished with tape and put into a resin cartridge (for Zip 100 available from Fuji Photo Film Co., Ltd.), to produce a flexible disk 10 having the layer structure shown in FIG. 1.

It should be noted that the stainless steel film forming roll 62 had a diameter of 600 mm and had channels 82 and 84 for circulating a refrigerant inside, and the surface temperature of the film forming roll 62 was controlled by circulating ethylene glycol of the refrigerant in the channels 82 and 84 at a flow rate of 5 L/minute. The channels 82 and 84 were placed at 20 mm or less from the surface of the film forming roll 62 in the depth direction.

### Example 12

A flexible disk 10 was produced in the same manner as Example 11 except for controlling the surface temperature of the film forming roll 62 at −20° C.

### Example 13

A flexible disk 10 was produced in the same manner as Example 11 except for controlling the surface temperature of the film forming roll 62 at 40° C.

### Example 14

A polyethylene terephthalate film having a thickness of 9 μm and a surface roughness Ra of 1.0 nm was used as the substrate 12, the first underlayer 16, second underlayer 18, magnetic layer 20, protective layer 22, and lubricant layer 24 were formed on one side of the substrate 12 in the same manner as Example 11, and a backcoating layer of carbon black was formed on the other side of the substrate 12 and slit without forming the first underlayer 16, second underlayer 18, magnetic layer 20, and protective layer 22, to produce a magnetic tape 10 having a width of 8 mm.

### Comparative Example 11

A flexible disk was produced in the same manner as Example 11 except for controlling the surface temperature of the film forming roll 62 at 80° C.

### Comparative Example 12

A flexible disk was produced in the same manner as Example 11 except for using a resin as a material of the film forming roll 62. The surface temperature of the film forming roll 62 varied within a range of 15 to 60° C.

### Comparative Example 13

A flexible disk was produced in the same manner as Example 11 except that tap water was used as cooling water and the surface temperature of the film forming roll 62 was not controlled. The surface temperature of the film forming roll 62 varied within a range of 15 to 30° C.

Then, the coercive forces Hc and distributions thereof of the samples were measured at positions located 100 m, 200 m, and 300 m from the end by using VSM to evaluate the magnetic characteristics.

The deformation of the substrate 12 was evaluated by visually observing each magnetic recording medium 10 to determine the presence of wrinkles, lines, and wavings.

Signals were recorded on each medium at a linear recording density of 400 kFCI and repeatedly reproduced with a GMR head having a reading track width of 0.25 μm and a read gap of 0.09 μm. At the time when the output dropped by 3 dB from the initial one, the running was stopped, and the running time was taken as a duration. The testing atmosphere was 23° C. and 50% RH, and the running test was terminated at 300 hours.

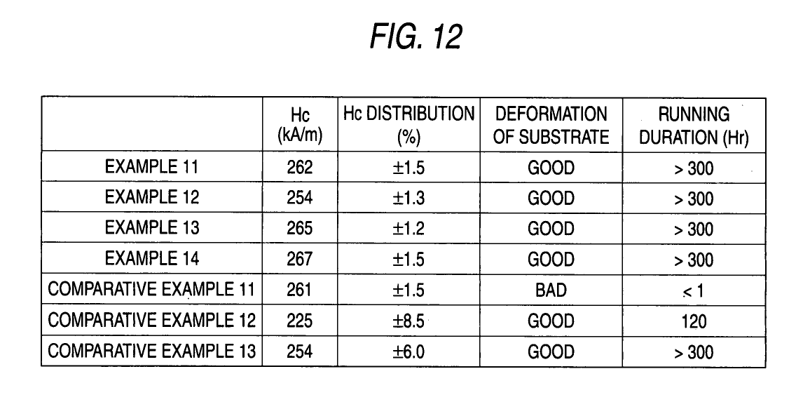

The results are shown in FIG. 12.

As is clear from the results shown in FIG. 12, the magnetic recording media 10 of Examples 11 to 14 produced according to the present invention exhibited excellent magnetic characteristics and no deformation of the substrate 12. The running durabilities of the media 10 were stable at a high level to achieve high productivity.

In contrast, in Comparative Example 11 using the film forming roll 62 with the surface temperature of 100° C., a clear line and crack was generated on the substrate 12 and the running durability was remarkably reduced though high magnetic characteristics could be obtained. Further, in Comparative Examples 12 and 13 where the surface temperatures of the film forming roll 62 were not within the scope of the invention, the Hc distributions were significantly deteriorated though the deformation of the substrate 12 was not observed.

Various changes may be made on materials, amounts, ratios, treatment details, treatment procedures, etc. in Examples without departing from the scope of the invention. Thus, the following specific examples should not be considered restrictive. The process and apparatus for producing a magnetic recording medium of the invention are not limited to the above embodiments, and obviously various changes may be made thereon without departing from the scope of the invention.

This application is based on Japanese Patent application JP 2005-10 628, filed Jan. 18, 2005 and Japanese Patent application JP 2005-37055 2, filed Dec. 22, 2005, the entire contents of which are hereby incorporated by reference, the same as if set forth at length.

What is claimed is:

1. A process for producing a magnetic recording medium comprising:
unrolling a flexible polymer substrate from a feed roll;
forming a magnetic layer on at least one side of the flexible polymer substrate by a vacuum film forming method in a film forming chamber, and
taking up the flexible polymer substrate on a take-up roll,
wherein at least one of the feed roll and the take-up roll is replaced while maintaining a vacuum state for forming the magnetic layer in the film forming chamber.

2. The process according to claim 1, wherein
a vacuum separator is placed between the film forming chamber and a roll chamber containing the feed roll and the take-up roll to selectably connect and close the roll chamber and the film forming chamber, and
at least one of the feed roll and the take-up roll is replaced while closing the roll chamber and the film forming chamber by the vacuum separator.

3. The process according to claim 2, wherein
the vacuum separator comprises a first shutter and a second shutter between the roll chamber and the film forming chamber, and the first shutter is closed to press a portion of the flexible polymer substrate unrolled from the feed roll and the second shutter is closed to press a portion to be taken up on the take-up roll, and
at least one of the feed roll and the take-up roll is replaced after the first shutter and the second shutter are closed to press the flexible polymer substrate.

4. The process according to claim 3, wherein
the first shutter comprises a first rigid member and a first elastic member that is selectably moved or deformed toward an end of the first rigid member,
the second shutter comprises a second rigid member and a second elastic member that is selectably moved or deformed toward an end of the second rigid member, and
at least one of the feed roll and the take-up roll is replaced after the first shutter and the second shutter are closed, the first elastic member is moved or deformed toward the end of the first rigid member, and the second elastic member is moved or deformed toward the end of the second rigid member, to press the flexible polymer substrate.

5. A process for producing a magnetic recording medium comprising forming a magnetic layer on at least one side of a flexible polymer substrate, wherein
at least the magnetic layer is formed on the flexible polymer substrate by a vacuum film forming method while bringing the flexible polymer substrate into close contact with a film forming roll having a controlled surface temperature within a predetermined temperature range.

6. The process according to claim 5, wherein after forming the magnetic layer, a protective layer is formed on the magnetic layer while bringing the flexible polymer substrate into close contact with the film forming roll having the controlled surface temperature within the predetermined temperature range.

7. The process according to claim 5, wherein the surface temperature of the film forming roll is controlled within a range of the predetermined temperature ±10° C.

8. The process according to claim 5, wherein the surface temperature of the film forming roll is controlled within a range of the predetermined temperature ±5° C.

9. The process according to claim 5, wherein the surface temperature of the film forming roll is controlled within a range of the predetermined temperature ±2° C.

10. The process according to claim 7, wherein the predetermined temperature is −20° C. to +40° C.

11. The process according to claim 5, wherein the temperature of the film forming roll is controlled by circulating a refrigerant inside the film forming roll at a flow rate of 3 L/minute or more.

12. The process according to any one of claims 5, wherein
the flexible polymer substrate comprises polyethylene terephthalate or polyethylene naphthalate, and
the magnetic layer is a granular magnetic layer.

13. An apparatus for producing a magnetic recording medium comprising a vacuum chamber, wherein
the vacuum chamber comprises:
a roll chamber containing a feed roll with a flexible polymer substrate wound and a take-up roll for taking up a treated flexible polymer substrate;
a film forming chamber for forming a magnetic layer on at least one side of the flexible polymer substrate unrolled from the feed roll; and
a vacuum separator capable of selectably connecting and closing the roll chamber and the film forming chamber to maintain a vacuum state in the film forming chamber even after the roll chamber is opened.

14. The apparatus according to claim 13, wherein
the film forming chamber comprises a film forming section for forming the magnetic layer and a film forming section for forming a protective layer on the magnetic layer, and
a gas mixing reducing member is provided between the film forming sections to reduce gas penetration.

15. The apparatus according to claim 13, wherein
the vacuum separator comprises a first shutter and a second shutter between the roll chamber and the film forming chamber, and the first shutter is for being closed to press a portion of the flexible polymer substrate unrolled from the feed roll and the second shutter is for being closed to press a portion to be taken up on the take-up roll, and
when the first shutter and the second shutter are closed and press the flexible polymer substrate, a vacuum state in the film forming chamber is maintained even after the roll chamber is opened.

16. The apparatus according to claim 15, wherein
the first shutter comprises a first rigid member and a first elastic member that is for being selectably moved or deformed toward an end of the first rigid member,
the second shutter comprises a second rigid member and a second elastic member that is for being selectably moved or deformed toward an end of the second rigid member, and
when the first shutter and the second shutter are closed, the first elastic member is moved or deformed toward the end of the first rigid member, and the second elastic member is moved or deformed toward the end of the second rigid member, the flexible polymer substrate is pressed.

17. The apparatus according to claim 16, wherein
the first rigid member and the second rigid member each independently have a Young's modulus of 7×10¹⁰ Pa or more and a maximum surface roughness Rz of 0.4 μm or less,
the first elastic member and the second elastic member each independently have a standard hardness of 50° or more, and
the elastic members apply a pressure of 0.3 MPa or more to the first rigid member and the second rigid member when the first shutter and the second shutter are closed.

18. The apparatus according to claim 13, wherein
the apparatus comprises a vacuum evacuation system for controlling vacuum degrees of the roll chamber and the film forming chamber at 1.0×10⁻⁴ Pa or less, and
the vacuum degree of the film forming chamber is maintained at 1×10⁻¹ Pa or less when the roll chamber is opened.

19. An apparatus for producing a magnetic recording medium by forming a magnetic layer on at least one side of a flexible polymer substrate, comprising
a film forming unit for forming at least the magnetic layer on the flexible polymer substrate by a vacuum film forming method while bringing the flexible polymer substrate into close contact with a film forming roll, and
a temperature control unit for controlling a surface temperature of the film forming roll within a predetermined temperature range.

20. The apparatus according to claim 19, wherein
after forming the magnetic layer, a protective layer is formed on the magnetic layer by the film forming unit while bringing the flexible polymer substrate into close contact with the film forming roll.

21. The apparatus according to claim 19, wherein the surface temperature of the film forming roll is controlled within a range of the predetermined temperature ±10° C. by the temperature control unit.

22. The apparatus according to claim 19, wherein the surface temperature of the film forming roll is controlled within a range of the predetermined temperature ±5° C. by the temperature control unit.

23. The apparatus according to claim 19, wherein the surface temperature of the film forming roll is controlled within a range of the predetermined temperature ±2° C. by the temperature control unit.

24. The apparatus according to claim 21, wherein the predetermined temperature is −20° C. to +40° C.

25. The apparatus according to claim 19, wherein the apparatus comprises a channel in which a refrigerant is circulated inside the film forming roll.

26. The apparatus according to claim 25, wherein the channel in which the refrigerant is circulated comprises a spiral channel along an outer circumference surface of the film forming roll.

27. The apparatus according to claim 25, wherein at least part of the channel is provided at 50 mm or less from a surface of the film forming roll in a depth direction.

28. The apparatus according to claim 19, wherein a surface of the film forming roll comprises a material having a specific heat of 0.5 J/g·K or less.

29. The apparatus according to claim 19, wherein
a surface of the film forming roll comprises at least one material selected from the group consisting of stainless steels, copper, and aluminum, and
the surface of the film forming roll is subjected to a hard chrome plating treatment.

30. The apparatus according to claim 19, wherein the film forming roll has a diameter of 350 mm or more.

31. The apparatus according to claim 19, wherein the film forming roll has a maximum surface roughness of 0.1 μm or less.
